(19) United States
(12) Patent Application Publication
(10) Pub. No.: US 2026/0038402 A1
(43) Pub. Date: Feb. 5, 2026

(54) TEST ELEMENT AND FABRICATING METHOD THEREOF

(71) Applicant: LG Display Co., Ltd., Seoul (KR)

(72) Inventors: Jae Kwang LEE, Paju-si (KR); Dae Han WON, Paju-si (KR); Hae Sung LEE, Paju-si (KR)

(73) Assignee: LG Display Co., Ltd., Seoul (KR)

(21) Appl. No.: 19/254,918

(22) Filed: Jun. 30, 2025

(30) Foreign Application Priority Data
Jul. 31, 2024 (KR) 10-2024-0102086

(51) Int. Cl. G09G 3/00; H10H 29/01; H10H 29/37

(52) U.S. Cl. CPC G09G 3/006; H10H 29/012; H10H 29/37; G09G 2330/12

(57) ABSTRACT

A test element may include a base layer, a bank on a portion of the base layer, a first layer on the base layer and on the bank, a photoresist layer on the first layer, the photoresist layer including a patterned area; and a second layer positioned on the photoresist layer. A height of a first area of the first layer on the bank may be greater than a height of a second area of the first layer on the base layer.

### CROSS-REFERENCE TO RELATED APPLICATION

This application claims priority to and the benefit of Korean Patent Application No. 10-2024-0102086, filed Jul. 31, 2024, the disclosure of which is incorporated herein by reference in its entirety.

### BACKGROUND

### Technical Field

The present disclosure relates to a test element and a method of fabricating the same.

### Discussion of the Related Art

Display devices are being employed in a variety of electronic devices, such as TVs, mobile phones, laptops, and tablets.

Examples of display devices include an organic light-emitting display (OLED) that emits light by itself and a liquid crystal display (LCD) that requires a separate light source.

In recent, a display device including a light-emitting element, such as a light-emitting diode (LED), has attracted attention as a next-generation display device. Because the light-emitting element is made of inorganic materials rather than organic materials, such a display device including a light-emitting element has a faster lighting speed, higher emission efficiency, and higher luminance as compared to liquid crystal displays and organic light-emitting displays.

### SUMMARY

When fabricating semiconductor devices by forming integrated circuits on a semiconductor wafer, it is necessary to measure the electrical characteristics of the integrated circuits to determine any defects or reliability issues of the integrated circuits.

Accordingly, embodiments of the present disclosure are directed to a test element and a method of fabricating the same that substantially obviates one or more of the problems due to limitations and disadvantages of the related art.

An aspect of the present disclosure is to provide a test element capable of determining reliability and a method of fabricating the same.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a test element may comprise: a base layer; a bank on a portion of the base layer; a first layer on the base layer and on the bank; a photoresist layer on the first layer, the photoresist layer including a patterned area; and a second layer positioned on the photoresist layer, wherein a height of a first area of the first layer on the bank is greater than a height of a second area of the first layer on the base layer.

In another aspect, a method of fabricating a test element may comprise forming a bank on a base layer; forming a first layer including a first area on the bank and a second area on the base layer; forming a photoresist layer on the first layer; forming a patterned area in the photoresist layer by exposure; and forming a second layer on the photoresist layer and in the patterned area, wherein a height of a first area of the first layer on the bank is greater than a height of a second area of the first layer on the base layer.

Specific details according to various examples of the present disclosure other than the means for solving the above-mentioned problems are included in the description and drawings below.

According to one or more embodiments of the present disclosure, the contact resistance between the first and second layers may be measured through the patterned area. As a result, it may be possible to determine the reliability of the micro-LEDs in the display device.

According to one or more embodiments of the present disclosure, by configuring a test element, defects in the display device may be detected. This may enable optimization of the process of the display device and reduction of greenhouse gas emissions from the production of the display device.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a perspective view illustrating a display device according to an embodiment of the present disclosure.

FIG. 2 is a plan view illustrating the display device according to an embodiment of the present disclosure.

FIG. 3 is an enlarged view illustrating the display device according to an embodiment of the present disclosure.

FIG. 4 is a diagram illustrating a circuit structure according to an embodiment of the present disclosure.

FIG. 5 is an enlarged plan view of a display area including a plurality of pixels.

FIG. 6 is plan views of the display device according to an embodiment of the present disclosure.

FIG. 7 is plan views of the display device according to an embodiment of the present disclosure.

FIG. 8 is a cross-sectional view of the display device according to an embodiment of the present disclosure.

FIG. 9 is a cross-sectional view illustrating the display device according to an embodiment of the present disclosure.

FIGS. 10 to 13 are diagrams illustrating an apparatus to which the display device according to embodiments of the present disclosure is applied.

FIG. 14 is a plan view illustrating a semiconductor device according to an embodiment of the present disclosure.

FIG. 15 is an enlarged view of an area A of FIG. 14.

FIG. 16 is a cross-sectional view of illustrating an example of a test element in which contact resistance between the first and second layers is not measured.

FIG. 17 is a diagram illustrating an example mask pattern used to generate the test element of FIG. 16.

FIG. 18 is a cross-sectional view illustrating a test element or a test element group according to an embodiment of the present disclosure.

FIG. 19 is a diagram illustrating a mask pattern forming the test element or the test element group of FIG. 18.

FIG. 20 is a plan view of the test element of FIG. 18.

FIG. 21 is a diagram illustrating an implementation of a test element or a test element group according to an embodiment of the present disclosure.

### DETAILED DESCRIPTION

Advantages and features of the present disclosure and a method of achieving the same should become clear with embodiments described in detail below with reference to the accompanying drawings. However, the present disclosure is not limited to the embodiments described below and may be implemented with a variety of different modifications. The embodiments are merely provided to allow those skilled in the art to completely understand the scope of the present disclosure.

The shapes, dimensions, ratios, angles, numbers, and the like disclosed in the drawings for describing the embodiments of the present disclosure are merely illustrative and are not limited to matters shown in the present disclosure. Like reference numerals refer to like elements throughout the disclosure. Further, in describing the present disclosure, detailed descriptions of well-known technologies will be omitted when it is determined that they may unnecessarily obscure the gist of the present disclosure. Terms, such as “including,” “having,” and “composed of,” used herein are intended to allow other elements to be added unless the terms are used with the term “only.” Any references to the singular may include the plural unless expressly stated otherwise.

Components are interpreted as including an ordinary error range even if no such margin is explicitly stated.

In the case of a description of a positional relationship, for example, in the case in which a position relationship between two portions is described with the terms “on,” “above,” “under,” “next to,” or the like, one or more portions may be interposed therebetween unless the term, for example, “right,” “directly,” or “near” is used in the expression.

For the description of a temporal relationship, when a temporal relationship is described as “after,” “subsequently to,” “next,” “before,” and the like, a non-consecutive case may be included unless the term “immediately” or “directly” is used in the expression.

Although the terms “first,” “second,” and the like may be used herein to describe various components, the components are not limited by the terms. These terms are used only to distinguish one component from another. Therefore, a first component described below may be a second component within the technological scope of the present disclosure.

Terms, first, second, A, B, (a), (b), or the like, may be used herein when describing components of the present disclosure. Such terms are used only to distinguish a component from another component, but do not limit the nature, sequence, order, number, or the like of components.

It is to be understood that when a component is described as being “connected,” “coupled,” “linked,” or “attached” to another component, the component may be directly connected, coupled, linked, or attached to the other component, but, unless specifically stated otherwise, still another component may be interposed between these two components so that they are indirectly connected, coupled, linked, or attached.

It is also to be understood that when a component or layer is described as being “in contact with” or “overlapping” another component or layer, the component or layer may be in direct contact with or directly overlapping the other component or layer, but, unless specifically stated otherwise, still another component or layer may be interposed between these two components or layers so that they are in indirect contact with or indirectly overlapping each other.

The term “at least one” should be understood as including any and all combinations of one or more of the associated listed components. For example, the meaning of “at least one of a first component, a second component, and a third component” denotes the combination of all components proposed from two or more of the first component, the second component, and the third component as well as the first component, the second component, or the third component.

The terms “first direction,” “second direction,” “third direction,” “X-axis direction,” “Y-axis direction,” and “Z-axis direction” should not be interpreted as referring only to geometrical relationships that are perpendicular to each other, but may indicate a broader range of directions within the functional scope of the configuration described in the present disclosure.

The features of various embodiments of the present disclosure may be partially or entirely combined with each other. The embodiments may be technically linked and operate in various ways and may be carried out independently of or in association with each other.

Hereinafter, various embodiments of the present disclosure will be described in detail with reference to the accompanying drawings.

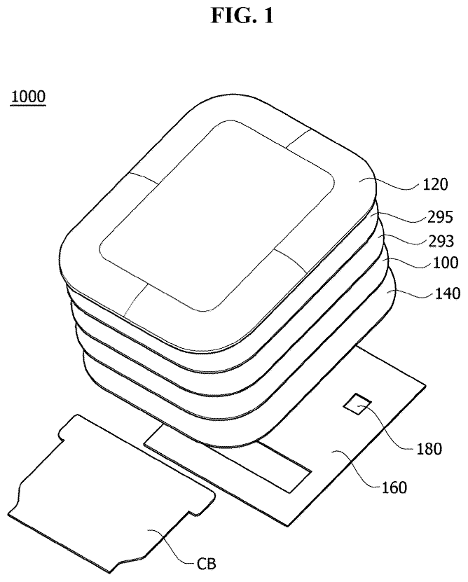

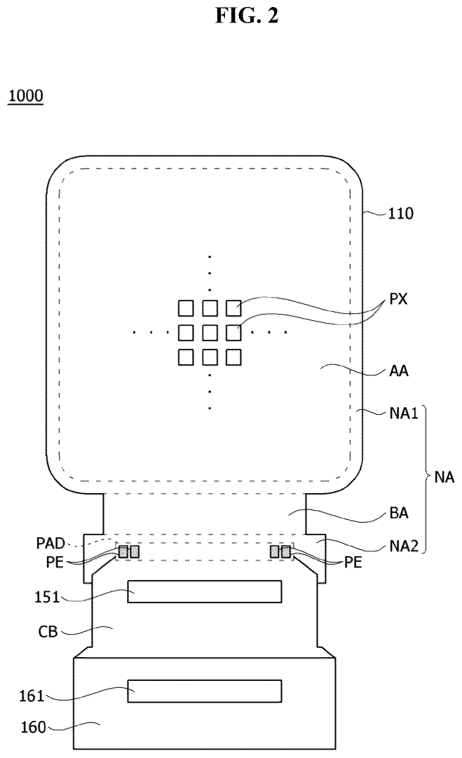

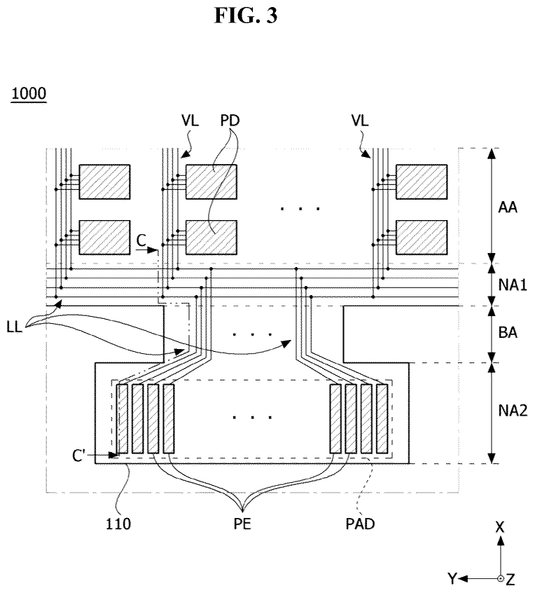

FIG. 1 is a perspective view illustrating a display device according to an embodiment of the present disclosure; FIG. 2 is a plan view illustrating the display device according to an embodiment of the present disclosure; FIG. 3 is an enlarged view illustrating the display device according to an embodiment of the present disclosure;

As shown in FIGS. 1 to 3, a display device 1000 according to an embodiment of the present disclosure may include a display panel 100, a polarizing layer 293, an adhesive layer 295, a cover member 120, a support substrate 140, a flexible circuit board CB, and a printed circuit board 160.

For example, the display device 1000 may include a substrate 110. The substrate 110 may be a member that supports other components of the display device 1000. The substrate 110 may be made of an insulating material. For example, the substrate 110 may be made of glass, resin or the like. The substrate 110 may also be made of a material having flexibility. For example, the substrate 110 may be made of a plastic material having flexibility, such as polyimide (PI). However, embodiments of the present disclosure are not limited thereto.

The display panel 100 may implement information, video, and/or images intended for the user. For example, the display panel 100 may include a display area AA and a non-display area NA. For example, the substrate 110 may include the display area AA and the non-display area NA. The term of the display area AA and the non-display area NA may not be limited to the substrate 110, but may be applied throughout the display device.

The display area AA may be an area where an image is displayed. The display area AA may include a plurality of pixels PX. Each of a plurality of pixels PX may be composed of a plurality of sub-pixels. A plurality of light-emitting elements may be arranged in each of the plurality of sub-pixels. The plurality of light-emitting elements may be configured differently depending on the type of display device 1000. For example, if the display device 1000 is an inorganic light-emitting display device, the light-emitting elements may be light-emitting diodes (LED), micro light-emitting diodes (micro LED), or mini light-emitting diodes (mini LED), but embodiments of the present disclosure are not limited thereto.

The non-display area NA may be an area where no image is displayed. Various wires and circuits for driving a plurality of light-emitting elements PX of the display area AA may be arranged in the non-display area NA. For example, in the non-display area NA, various wires and driving circuits may be mounted and a pad part PAD may be arranged to which integrated circuits, printed circuits, etc. are connected, but embodiments of the present disclosure are not limited thereto.

For example, the driving circuits may be a data driving circuit and/or a gate driving circuit, but embodiments of the present disclosure are not limited thereto. Wires to which control signals for controlling the driving circuits are supplied may be arranged. For example, the control signals may include various timing signals including clock signals, input data enable signals, and synchronization signals, but embodiments of the present disclosure are not limited thereto. The control signals may be received through the pad part PAD. For example, link wires LL for transmitting signals may be arranged in the non-display area NA. For example, driving components, such as a flexible circuit board CB and a printed circuit board 160 may be connected to the pad part PAD.

According to examples of the present disclosure, the non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1, and may be a bendable area. The second non-display area NA2 is an area extending from the bending area BA, in which the pad part PAD may be arranged. For example, the bending area BA may be in a bent state, and the remaining area of the substrate 110 other than the bending area BA may be in a flat state. In this configuration, as the bending area BA is bent, the second non-display area NA2 may be located on the rear surface of the display area AA. However, embodiments of the present disclosure are not limited thereto.

The display area AA of the substrate 110 or the display device 1000 may be configured in a variety of shapes depending on the design of the display device 1000. For example, the display area AA may be configured as a rectangular shape with four rounded corners, but embodiments of the present disclosure are not limited thereto. For another example, the display area AA may be configured as a rectangular shape with four right-angled corners, a circular shape, or the like, but embodiments of the present disclosure are not limited thereto.

According to examples of the present disclosure, the width of the second non-display area NA2 in which the plurality of pad electrodes PE are arranged, may be wider than the width of the bending area BA in which only the plurality of link wires LL are arranged. Furthermore, the width of the display area AA in which the plurality of sub-pixels are arranged may be wider than the width of the bending area BA in which only the plurality of link wires LL is arranged. While the width of the bending area BA is shown to be narrower than the width of other areas of the substrate 110 in this drawing, the shape of the substrate 110 including the bending area BA is communication wires, and embodiments of the present disclosure are not limited thereto.

With reference to FIG. 3, a plurality of pixel driving circuits PD may be arranged in the display area AA. The plurality of pixel driving circuits PD may be circuits for driving the light-emitting elements of a plurality of sub-pixels. Each of the plurality of pixel driving circuits PD includes a plurality of transistors, including a driving transistor, and a storage capacitor or the like, and may supply control signals, power, and driving currents to the light-emitting elements of the plurality of sub-pixels to control the emission operation of the plurality of light-emitting elements. For example, the pixel driving circuits PD may include power wires and signal wires for controlling the emission on/off and/or emission time of the light-emitting elements. For example, the plurality of pixel driving circuits PD may be drive drivers manufactured on a semiconductor substrate using a metal-oxide-silicon field effect transistor (MOSFET) manufacturing process, but embodiments of the present disclosure are not limited thereto. The drive driver may include the plurality of pixel driving circuits PD and may drive the plurality of sub-pixels.

As shown in FIG. 1, the flexible circuit board CB and the printed circuit board 160 may be arranged on a lower portion of the display panel 100.

The flexible circuit board CB and the printed circuit board 160 may be arranged on at least one side edge of the display panel 100, but embodiments of the present disclosure are not limited thereto. One side of the flexible circuit board CB may be attached to the display panel 100, and the other side may be attached to the printed circuit board 160, but embodiments of the present disclosure are not limited thereto. The flexible circuit board CB may be a flexible film, but embodiments of the present disclosure are not limited thereto.

The pad part PAD including a plurality of pad electrodes PE may be arranged in the second non-display area NA2. Driving components including one or more flexible circuit boards (or flexible films) CB and printed circuit boards 160 may be attached to or bonded to the pad part PAD. The plurality of pad electrodes PE of the pad part PAD are electrically connected to one or more flexible circuit boards (or flexible film) CB, and various signals (or power) from the printed circuit boards 160 and the flexible circuit boards (or flexible films) CB may be transmitted to the plurality of pixel driving circuits PD of the display area AA.

A flexible circuit board (or flexible film) CB may be a film with various components placed on a flexible base film. For example, a drive IC, such as a gate driver IC or a data driver IC, may be located on the flexible circuit board (or flexible film) CB, but embodiments of the present disclosure are not limited thereto. The drive IC may be a component that processes data and driving signals for displaying the image. The drive IC may be arranged in a manner, such as a chip on glass (COG), a chip on film (COF), or a tape carrier package (TCP), depending on how it is mounted, but embodiments of the present disclosure are not limited thereto. The flexible circuit board (or flexible film) CB may be attached or bonded to the plurality of pad electrodes PE through a conductive adhesive layer, but embodiments of the present disclosure are not limited thereto. For example, the flexible circuit board CB may include a control circuit that is a timing controller 151, TCON.

The printed circuit board 160 may be electrically connected to one or more flexible circuit boards (or flexible films) CB and may be a component that supplies signals to the drive ICs. The printed circuit board 160 may be arranged on one side of the flexible circuit board (or flexible film) CB and electrically connected to the flexible circuit board (or flexible film) CB.

A variety of components for supplying different signals to the drive IC may be arranged on the printed circuit board 160. For example, various components, such as a timing controller, a power supply, a memory, or a processor, may be arranged on the printed circuit board 160. For example, the printed circuit board 160 may include a power management integrated circuit (PMIC) (161), but embodiments of the present disclosure are not limited thereto.

The printed circuit board 160 may include at least one hole 180, but embodiments of the present disclosure are not limited thereto. An internal component for sensing ambient light or temperature that may be provided to a plurality of sensors may be arranged in an area corresponding to the at least one hole 180. For example, the internal component may include an ambient light sensor (ALS) or a temperature sensor, but embodiments of the present disclosure are not limited thereto. For example, the hole 180 may be a transmissive hole or the like, but embodiments of the present disclosure are not limited thereto.

As illustrated in FIG. 1, the polarizing layer 293 may be located on the display panel 100. The polarizing layer 293 may prevent or reduce light generated by an external light source from entering the inside of the display panel 100 and affecting the light-emitting elements or the like.

The cover member 120 may be arranged on the polarizing layer 293. The cover member 120 may be a member for protecting the display panel 100. The adhesive layer 295 may be arranged between the polarizing layer 293 and the cover member 120. The cover member 120 may be attached to the display panel 100 by the adhesive layer 295. The adhesive layer 295 may include, but is not limited to, an optically clear adhesive (OCA), an optically cleared resin (OCR), or a pressure sensitive adhesive (PSA).

The support substrate 140 may be arranged between the display panel 100 and the printed circuit board 160. The support substrate 140 may reinforce the rigidity of the display panel 100. The support substrate 140 may be a back plate, but embodiments of the present disclosure are not limited thereto.

With reference to FIGS. 1 to 3, a plurality of link wires LL may be arranged in the non-display area NA. The plurality of link wires LL may be wires that carries various signals from one or more flexible circuit boards (or flexible films) CB and printed circuit boards 160 to the display area AA. The plurality of link wires LL may extend from the plurality of pad electrodes PE in the second non-display area NA2 toward the bending area BA and the first non-display area NA1, and may be electrically connected to a plurality of driving wires VL in the display area AA. The plurality of pixel driving circuits PD may be driven by signals received from one or more flexible circuit boards (or flexible films) CB and printed circuit boards 160 through the driving wires VL in the display area AA and the link wires LL in the non-display area NA.

For example, the plurality of driving wires VL may be wires for carrying signals output from the flexible circuit board (or flexible film) CB and the printed circuit board 160, along with a plurality of link wires LL, to the plurality of pixel driving circuits PD. The plurality of driving wires VL may be arranged in the display area AA and electrically connected to each of the plurality of pixel driving circuits PD. The plurality of driving wires VL may extend from the display area AA toward the non-display area NA and may be electrically connected to the plurality of link wires LL. Therefore, the signals output from the flexible circuit board (or flexible film) CB and the printed circuit board 160 may be transmitted to each of the plurality of pixel driving circuits PD through the plurality of link wires LL and the plurality of driving wires VL.

When the bending area BA is bent, portions of the plurality of link wires LL may be bent accordingly. Stress is concentrated in portions of the bent link wires LL, which may cause the link wires LL to crack. Accordingly, the plurality of link wires LL may be formed of a conductive material having excellent ductility to reduce cracking during bending of the bending area BA. For example, the plurality of link wires LL may be formed of a conductive material having excellent ductility, such as gold (Au), silver (Ag), aluminum (Al), and the like, but embodiments of the present disclosure are not limited thereto. The plurality of link wires LL may also be formed of one of a variety of conductive materials used in the display area AA. For example, the plurality of link wires LL may be formed of molybdenum (Mo), chromium (Cr), titanium (Ti), nickel (Ni), neodymium (Nd), copper (Cu), and alloys of silver (Ag) and magnesium (Mg), or alloys thereof, but embodiments of the present disclosure are not limited thereto. The plurality of link wires LL may be formed of a multi-layer structure including various conductive materials. For example, the plurality of link wires LL may be formed of a triple-layer structure of titanium (Ti)/aluminum (Al)/titanium (Ti), but embodiments of the present disclosure are not limited thereto.

The plurality of link wires LL may be configured in various shapes to reduce stress. At least a portion of the plurality of link wires LL arranged in the bending area BA may extend in the same direction as the extension of the bending area BA, or may extend in a direction different from the extension of the bending area BA to reduce stress. For example, if the bending area BA extends in one direction from the first non-display area NA1 toward the second non-display area NA2, at least a portion of the link wires LL arranged on the bending area BA may extend in a direction that is inclined relative to the one direction. For another example, at least a portion of the plurality of link wires LL may be configured in a pattern of various shapes. For example, at least a portion of the plurality of link wires LL arranged in the bending area BA may be a shape in which a conductive pattern having at least one of a diamond shape, a rhombus shape, a trapezoidal shape, a triangular wave shape, a sawtooth wave shape, a sinusoidal shape, a circular shape, and an omega shape is repeatedly arranged, but embodiments of the present disclosure are not limited thereto. Therefore, to minimize or at least reduce stresses concentrated in the plurality of link wires LL and resulting cracking, the shape of the plurality of link wires LL may be of various shapes including the shapes described above, but embodiments of the present disclosure are not limited thereto.

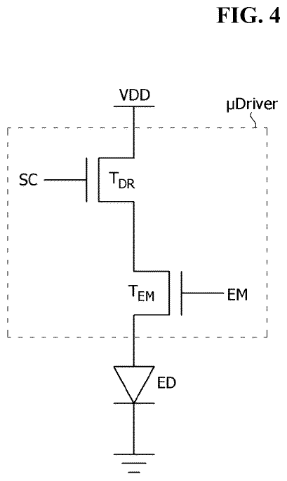

FIG. 4 is a diagram illustrating a circuit structure according to an embodiment of the present disclosure.

Although FIG. 4 illustrates one light-emitting element ED connected to a micro-driver μDriver, the present disclosure is not limited thereto. For example, eight light-emitting elements ED may be connected to one micro-driver μDriver. For another example, 16 light-emitting elements ED may be connected to one micro-driver, or 32 light-emitting elements ED or 64 light-emitting element ED may be connected to one micro-driver simultaneously. The light-emitting element ED may be a micro light-emitting light-emitting element μLED.

One micro-driver μDriver may include a driving transistor T_{DR} and a light-emitting transistor T_{EM}, but embodiments of the the present disclosure are not limited thereto. For example, the driving transistor T_{DR} may have a first electrode to which a high potential power voltage VDD is applied, a second electrode connected to a first electrode of the light-emitting transistor T_{EM}, and a gate electrode to which a scan signal SC is applied. The scan signal SC applied to the gate electrode of the driving transistor T_{DR} may be a direct current voltage that is applied as a fixed reference voltage (Vref) for each frame, but embodiments of the present disclosure are not limited thereto.

The light-emitting transistor T_{EM} may have a first electrode connected to the second electrode of the driving transistor T_{DR}, a second electrode connected to the light-emitting element ED, and a gate electrode to which the emission signal EM is applied. The emission signal EM applied to the gate electrode of the light-emitting transistor T_{EM} may be a pulse width modulation signal that varies every frame, but embodiments of the present disclosure are not limited thereto.

The light-emitting element ED may have a first electrode connected to a second electrode of the light-emitting transistor T_{EM} and a second electrode to ground. For example, the first electrode may be an anode electrode and the second electrode may be a cathode electrode, but embodiments of the present disclosure are not limited thereto. Each of the driving transistor T_{DR} and the light-emitting transistor T_{EM} may be n-type transistors or p-type transistors.

In the micro-driver μDriver, the driving transistor T_{DR} may be turned on by the scan signal SC applied from the timing controller T-CON, and the light-emitting transistor TEM may be turned on by the light-emitting signal EM. Accordingly, a driving current is applied to the light-emitting element ED through the driving transistor T_{DR} and the light-emitting transistor T_{EM} by the high-potential power voltage VDD applied to the first electrode of the driving transistor T_{DR}, thereby causing the light-emitting element ED to emit light.

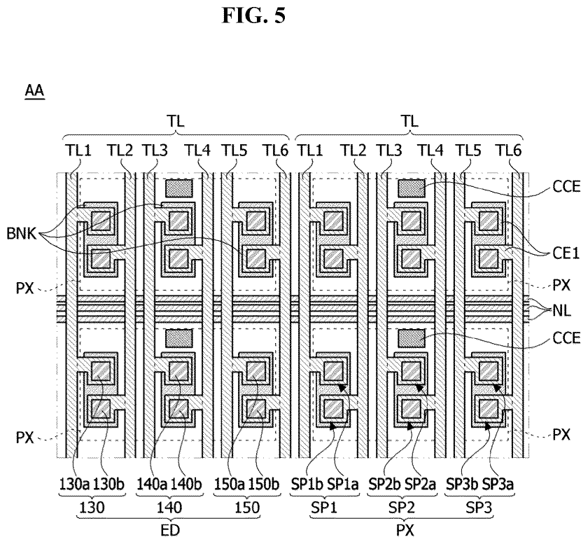

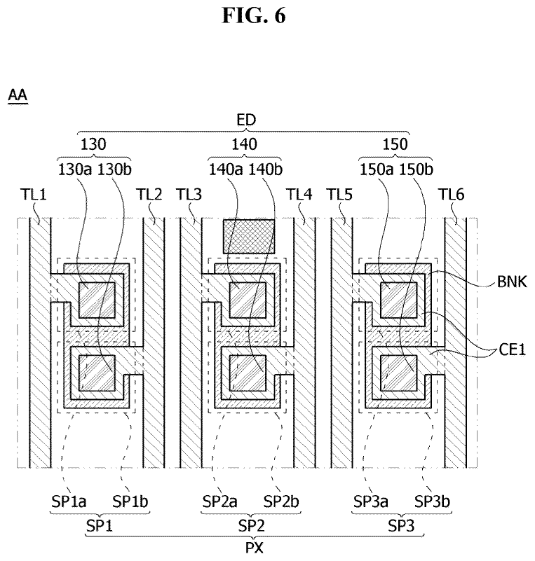

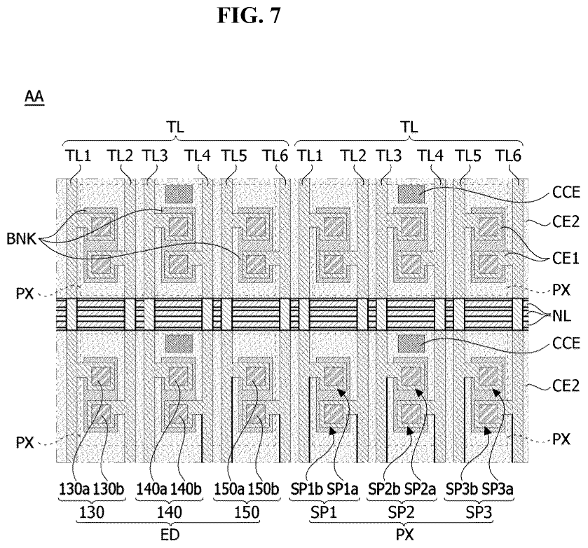

FIGS. 5 to 7 are plan views of the display device according to an embodiment of the present disclosure. For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. While FIGS. 5 and 6 illustrate only a plurality of signal wires TL, a plurality of communication wires NL, a plurality of first electrodes CE1, a plurality of banks BNK, and a plurality of light-emitting elements ED, embodiments of the present disclosure are not limited thereto. FIG. 7 is an enlarged plan view in which a plurality of second electrodes CE2 are additionally arranged in FIG. 5.

As shown in FIGS. 5 to 6, a plurality of pixels PX composed of a plurality of sub-pixels may be arranged in the display area AA. Each of the plurality of sub-pixels may include an light-emitting element ED, that may independently emit light. The plurality of sub-pixels may be arranged in a matrix, forming a plurality of rows and a plurality of columns, but embodiments of the present disclosure are not limited thereto.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another may be a green sub-pixel, and the remaining may be a blue sub-pixel. The types of the plurality of sub-pixels are illustrative, and embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may be composed of a first-first sub-pixel SP1a and a first-second sub-pixel SP1b. The pair of second sub-pixels SP2 may be composed of a second-first sub-pixel SP2a and a second-second sub-pixel SP2b. The pair of third sub-pixels SP3 may be composed of a third-first sub-pixel SP3a and a third-second sub-pixel SP3b. For example, one pixel PX may include a first-first sub-pixel SP1a and a first-second sub-pixel SP1b, a second-first sub-pixel SP2a and a second-second sub-pixel SP2b, and a third-first sub-pixel SP3a and a third-second sub-pixel SP3b, but embodiments of the present disclosure are not limited thereto.

The plurality of sub-pixels that constitute one pixel PX may be arranged in a variety of ways. For example, in one pixel PX, a pair of first sub-pixels SP1 may be arranged in the same column, a pair of second sub-pixels SP2 may be arranged in the same column, and a pair of third sub-pixels SP3 may be arranged in the same column. The first sub-pixel SP1, the second sub-pixel SP2, and the third sub-pixel SP3 may be arranged in the same row. The number and arrangement of the plurality of sub-pixels constituting one pixel PX are examples, and embodiments of the present disclosure are not limited thereto.

A plurality of signal wires TL may be arranged in the area between the plurality of sub-pixels. The plurality of signal wires TL may extend in the column direction between the plurality of sub-pixels. The plurality of signal wires TL may be wires that carry anode voltages from the pixel driving circuit PD to the plurality of sub-pixels. For example, the plurality of signal wires TL may be electrically connected to the plurality of pixel driving circuits PD and the first electrodes CE1 of the plurality of sub-pixels. The anode voltages output from the pixel driving circuits PD may be transmitted to the first electrodes CE1 of the plurality of sub-pixels through the plurality of signal wires TL. For example, a first electrode CE1 may be an electrode electrically connected to the anode electrode 134 of the light-emitting element ED. Therefore, the anode voltage from the signal wire TL may be transmitted to the anode electrode 134 of the light-emitting element ED through the first electrode CE1.

Consequently, instead of forming a plurality of transistors and storage capacitors for each of the plurality of sub-pixels, the structure of the display device 1000 may be simplified using the pixel driving circuits PD with an integrated plurality of pixel circuits. In addition, by integrating the circuits arranged for each of the plurality of sub-pixels into a single pixel driving circuit PD, high-efficiency, low-power operation may be achieved.

The plurality of signal wires TL may include a first signal wire TL1, a second signal wire TL2, a third signal wire TL3, a fourth signal wire TL4, a fifth signal wire TL5, and a sixth signal wire TL6. Each of the first signal wire TL1 and the second signal wire TL2 may be electrically connected to each of the pair of first sub-pixels SP1. Each of the third signal wire TL3 and the fourth signal wire TL4 may be electrically connected to each of the pair of second sub-pixels SP2. Each of the fifth signal wire TL5 and the sixth signal wire TL6 may be electrically connected to each of the pair of third sub-pixels SP3.

The first signal wire TL1 may be arranged on one side of the pair of first sub-pixels SP1, and the second signal wire TL2 may be arranged on the other side of the pair of first sub-pixels SP1. The first signal wire TL1 may be electrically connected to the first electrode CE1 of one of the pair of first sub-pixels SP1, for example, the first-first sub-pixel SP1a. The second signal wire TL2 may be electrically connected to the first electrode CE1 of the remaining of the pair of first sub-pixels SP1, for example, the first-second sub-pixel SP1b.

The third signal wire TL3 may be arranged on one side of the pair of second sub-pixels SP2, and the four signal wire TL4 may be arranged on the other side of the pair of second sub-pixels SP2. For example, the third signal wire TL3 may be arranged adjacent to the second signal wire TL2. The third signal wire TL3 may be electrically connected to the first electrode CE1 of one of the pair of second sub-pixels SP2, for example, the second-first sub-pixel SP2a. The fourth signal wire TL4 may be electrically connected to the first electrode CE1 of the remaining of the pair of second sub-pixels SP2, for example, the second-second sub-pixel SP2b.

The fifth signal wire TL5 may be arranged on one side of the pair of third sub-pixels SP3, and the sixth signal wire TL6 may be arranged on the other side of the pair of third sub-pixels SP3. For example, the fifth signal wire TL5 may be arranged adjacent to the fourth signal wire TL4. The sixth signal wire TL6 may be arranged adjacent to the first signal wire TL1 connected to its neighboring pixel PX. The fifth signal wire TL5 may be electrically connected to the first electrode CE1 of one of the pair of third sub-pixels SP3, for example, the third-first sub-pixel SP3a. The sixth signal wire TL6 may be electrically connected to the first electrode CE1 of the remaining of the pair of third sub-pixels SP3, for example, the third-second sub-pixel SP3b.

The plurality of signal wires TL may be made of a conductive material. For example, the plurality of signal wires TL may be formed of conductive materials, such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like, but embodiments of the present disclosure are not limited thereto. For another example, the plurality of signal wires TL may be formed of a multi-layer structure of a conductive material. For example, the plurality of signal wires TL may be formed of a multi-layer structure of Titanium (Ti)/Aluminum (Al)/Titanium (Ti)/Indium Tin Oxide (ITO), but embodiments of the present disclosure are not limited thereto.

The plurality of communication wires NL may be arranged in the area between the plurality of pixels PX. The plurality of communication wires NL may be arranged extending in the row direction in an area between the plurality of pixels PX. The plurality of communication wires NL may be arranged in an area between the plurality of second electrodes CE2, and may not overlap the plurality of second electrodes CE2. For example, the plurality of communication wires NL may be wires used for short-range communication, such as near field communication (NFC). The plurality of communication wires NL may function as antennas. For example, the plurality of communication wires NL may be a plurality of connection wires or the like, but embodiments of the present disclosure are not limited thereto.

According to example embodiments of the present disclosure, a bank BNK may be positioned in each of the plurality of sub-pixels. A plurality of banks BNK may be structures in which a plurality of light-emitting elements ED are seated. The plurality of banks BNK may serve to guide the positioning of the plurality of light-emitting elements ED during a transfer process of transferring the plurality of light-emitting elements ED to the display device 1000. In the process of transferring a plurality of light-emitting elements ED, the plurality of light-emitting elements ED may be transferred onto the plurality of banks BNK. The plurality of banks BNK may be bank patterns or structures, or the like, but embodiments of the present disclosure are not limited thereto.

A bank BNK of the first sub-pixel SP1, a bank BNK of the second sub-pixel SP2, and a bank BNK of the third sub-pixel SP3 may be arranged to be spaced apart from each other. The bank BNK of the first sub-pixel SP1, the bank BNK of the second sub-pixel SP2, and the bank BNK of the third sub-pixel SP3 may be configured to be separated. Thus, the banks BNK of the first sub-pixels SP1, the second sub-pixels SP2, and the third sub-pixels SP3, to which different types of light-emitting elements ED are transferred, may be easily identified.

The bank BNK of the first-first sub-pixel SP1a and the bank BNK of the first-second sub-pixel SP1b may be connected to each other, or may be spaced apart from each other or formed separately from each other. For example, the bank BNK of the first-first sub-pixel SP1a and the bank BNK of the first-second sub-pixel SP1b, in which the same type of light-emitting elements ED are arranged, may be connected to each other, spaced apart, or separated from each other in consideration of the design, such as the transfer process requirements, etc. The bank BNK of the second-first sub-pixel SP2a and the bank BNK of the second-second sub-pixel SP2b may also be connected to each other, or may also be spaced apart or separated from each other. The bank BNK of the third-first sub-pixel SP3a and the bank BNK of the third-second sub-pixel SP3b may also be connected to each other, or may be spaced apart from each other or formed separately from each other. Therefore, the banks BNK of the pair of first sub-pixels SP1, the banks BNK of the pair of second sub-pixels SP2, and the bank BNKs of the pair of third sub-pixels SP3 may be formed in various ways, and embodiments of the present disclosure are not limited thereto.

For example, the plurality of banks BNK may be made of an organic insulating material. The plurality of banks BNK may be formed of a single or multiple layers of an organic insulating material. For example, the plurality of banks BNK may be formed of a photo resist, polyimide (PI), or acryl-based material, but embodiments of the present disclosure are not limited thereto.

The first electrode CE1 may be positioned on each of the plurality of sub-pixels. The first electrode CE1 may be positioned on the bank BNK. The first electrode CE1 may be electrically connected to one of the plurality of signal wires TL. At least a portion of the first electrode CE1 may extend outwardly of the bank BNK and may be electrically connected to the signal wire TL closest to the first electrode CE1. For example, a portion of the first electrode CE1 of the first-first sub-pixel SP1a may extend to one side area of the first-first sub-pixel SP1a and be electrically connected to the first signal wire TL1, and a portion of the first electrode CE1 of the first-second sub-pixel SP1b may extend to the other side area of the first-second sub-pixel SP1b and be electrically connected to the second signal wire TL2. A portion of the first electrode CE1 of the second-first sub-pixel SP2a may extend to one side area of the second-first sub-pixel SP2a and be electrically connected to the third signal wire TL3, and a portion of the first electrode CE1 of the second-second sub-pixel SP2b may extend to the other side area of the second-second sub-pixel SP2b and be electrically connected to the fourth signal wire TL4. A portion of the first electrode CE1 of the third-first sub-pixel SP3a may extend to one side area of the third-first sub-pixel SP3a and be electrically connected to the fifth signal wire TL5, and a portion of the first electrode CE1 of the third-second sub-pixel SP3b may extend to the other side area of the third-second sub-pixel SP3b and be electrically connected to the sixth signal wire TL6.

The first electrode CE1 is electrically connected to the anode electrode 134 of the light-emitting element ED, and may transmit the anode voltage from the pixel driving circuit PD to the light-emitting element ED through the signal wire TL. Different voltages may be applied to the first electrode CE1 of each of the plurality of sub-pixels according to the image being displayed. For example, different voltages may be applied to the first electrode CE1 of each of the plurality of sub-pixels. The first electrode CE1 may be a pixel electrode, and embodiments of the present disclosure are not limited thereto.

The first electrode CE1 may be formed of a conductive material. For example, the first electrode CE1 may be integrally configured with the plurality of signal wires TL. For example, the first electrode CE1 may be formed of the same conductive material as the plurality of signal wires TL, but embodiments of the present disclosure are not limited thereto. For example, the first electrode CE1 may be formed of a conductive material, such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like, but embodiments of the present disclosure are not limited thereto. For another example, the first electrode CE1 may be formed of a multi-layer structure of a conductive material. For example, the plurality of first electrodes CE1 may be made of a multi-layer structure of Titanium (Ti)/Aluminum (Al)/Titanium (Ti)/Indium Tin Oxide (ITO), but embodiments of the present disclosure are not limited thereto.

The light-emitting element ED may be arranged in each of the plurality of sub-pixels. A plurality of light-emitting elements ED may be either light-emitting diodes (LED) or micro LED, but embodiments of the present disclosure are not limited thereto. The plurality of light-emitting elements ED may be arranged on the bank BNK and the first electrode CE1. The plurality of light-emitting elements ED are arranged on the first electrode CE1 and may be electrically connected to the first electrode CE1. Therefore, the light-emitting element ED may emit light by receiving an anode voltage from the pixel driving circuit PD through the signal wire TL and the first electrode CE1.

The plurality of light-emitting elements ED may include a first light-emitting element 130, a second light-emitting element 140, and a third light-emitting element 150. The first light-emitting element 130 may be arranged in the first sub-pixel SP1. The second light-emitting element 140 may be arranged in the second sub-pixel SP2. The third light-emitting element 150 may be arranged in the third sub-pixel SP3. For example, one of the first light-emitting element 130, the second light-emitting element 140, and the third light-emitting element 150 may be a red light-emitting element, another may be a green light-emitting element, and the remaining may be a blue light-emitting element, but embodiments of the present disclosure are not limited thereto. Accordingly, various colors of light, including white, may be implemented by combining red light, green light, and blue light emitted by the plurality of light-emitting elements ED. The types of the plurality of light-emitting elements ED are examples, and embodiments of the present disclosure are not limited thereto.

The first light-emitting element 130 may include the first-first light-emitting element 130a arranged in the first-first sub-pixel SP1a and the first-second light-emitting element 130b arranged in the first-second sub-pixel SP1b. The second light-emitting element 140 may include the second-first light-emitting element 140a arranged in the second-first sub-pixel SP2a and the second-second light-emitting element 140b arranged in the second-second sub-pixel SP2b. The third light-emitting element 150 may include a third-first light-emitting element 150a arranged in the third-first sub-pixel SP3a and the third-second light-emitting element 150b arranged in the third-second sub-pixel SP3b.

As shown in FIGS. 5 and 6, together with FIG. 7, the second electrode CE2 may be arranged on each of the plurality of sub-pixels. The second electrode CE2 may be positioned on the light-emitting element ED. The second electrode CE2 may be electrically connected to the pixel driving circuit PD through a plurality of contact electrodes CCE.

For example, the second electrode CE2 may be electrically connected to a cathode electrode 135 of the light-emitting element ED to transmit the cathode voltage from the pixel driving circuit PD to the light-emitting element ED. The same cathode voltage may be applied to the second electrode CE2 of each of the plurality of sub-pixels. For example, the same voltage may be applied to the second electrode CE2 of each of the plurality of sub-pixels and the cathode electrode 135 of the light-emitting element ED. Thus, the second electrode CE2 may be a common electrode, but embodiments of the present disclosure are not limited thereto.

At least some of the plurality of sub-pixels may share the second electrode CE2. At least some of the second electrodes CE2 of the plurality of sub-pixels may be electrically connected to each other. Because the same voltage is applied to the second electrodes CE2, at least some of the second electrodes CE2 of the sub-pixels may be shared and used. For example, the second electrodes CE2 of at least some of the plurality of pixels PX arranged in the same row may be connected to each other. For example, one second electrode CE2 may be arranged on a plurality of pixels PX. One second electrode CE2 may be arranged for each of n sub-pixels.

For example, some of the second electrodes CE2 of the plurality of sub-pixels may be spaced apart or separated from each other. For example, the second electrode CE2 connected to an (n)th row of pixels PX and the second electrode CE2 connected to an (n+1)th row of pixels PX may be spaced apart or separated from each other. For example, the plurality of second electrodes CE2 may be spaced apart from each other with a plurality of communication wires NL extending in the row direction interposed therebetween. Thus, the number of the plurality of sub-pixels may be greater than the number of the plurality of second electrodes CE2. For another example, the second electrodes CE2 of the plurality of sub-pixels may all be connected to each other so that only one second electrode CE2 is arranged on the substrate 110, and embodiments of the present disclosure are not limited thereto.

The plurality of second electrodes CE2 may be formed of a transparent conductive material, but embodiments of the present disclosure are not limited thereto. The plurality of second electrodes CE2 may be made of a transparent conductive material, such that light emitted from the light-emitting element ED is directed onto the upper portion of the second electrode CE2. For example, the second electrode CE2 may made of a transparent conductive material, such as Indium Tin Oxide (ITO), Indium Zinc Oxide (IZO), Indium Gallium Zinc Oxide (IGZO), or the like, but embodiments of the present disclosure are not limited thereto.

A plurality of contact electrodes CCE may be positioned on the substrate 110. For example, a plurality of contact electrodes CCE may be positioned to be spaced apart from the plurality of banks BNK and the plurality of signal wire TL. Each of the plurality of second electrodes CE2 may overlap at least one contact electrode CCE. For example, one second electrode CE2 may overlap a plurality of contact electrodes CCE.

For example, a plurality of contact electrodes CCE may be electrically connected to a plurality of second electrodes CE2. The plurality of contact electrodes CCE are arranged between the substrate 110 and the plurality of second electrodes CE2 to supply the cathode voltage from the pixel driving circuit PD to the second electrodes CE2.

For example, when micro-LEDs are used as the light-emitting elements ED, the display device 1000 may be manufactured by forming a plurality of micro-LEDs on a wafer and transferring the micro-LEDs onto the substrate 110 of the display device 1000. Various defects may occur in the process of transferring a plurality of light-emitting elements ED having a fine size from a wafer to the substrate 110. For example, in some sub-pixels, there may be a non-transferred defect in which the light-emitting element ED is not transferred, and in other sub-pixels, there may be a defect caused by alignment error in which the light-emitting element ED is transferred out of position. In addition, the transfer process has been completed normally, but the transferred light-emitting element ED itself may be defective. Thus, a plurality of homogeneous light-emitting elements ED may be transferred to one sub-pixel, taking into account the defects during the transfer process of a plurality of light-emitting elements ED. A lighting test of the plurality of light-emitting elements ED is conducted, and only one light-emitting element ED that has been finally determined to be normal may be used.

For example, the first-first light-emitting element 130a and the first-second light-emitting element 130b may be transferred together onto one pixel PX and inspected for defects. If both the first-first light-emitting element 130a and the first-second light-emitting element 130b are determined to be normal, only the first-first light-emitting element 130a may be used and the first-second light-emitting element 130b may not be used. For another example, if only the first-second light-emitting element 130b is determined to be normal among the first-first light-emitting element 130a and the first-second light-emitting element 130b, the first-first light-emitting element 130a may not be used and only the first-second light-emitting element 130b may be used. Accordingly, even if multiple light-emitting elements ED of the same type are transferred onto a single pixel PX, only one light-emitting element ED may be used at the end.

As a result, one of a pair of light-emitting elements ED may be a main or primary light-emitting device ED and the other light-emitting element ED may be a redundancy light-emitting element ED. The redundancy light-emitting element ED may be a spare light-emitting element ED in preparation for a defect in the main light-emitting element ED. The redundancy light-emitting element ED may be used as a replacement in case the main light-emitting element ED is defective. Therefore, transferring the main and redundancy light-emitting elements ED together onto a single pixel PX may minimize or at least reduce the deterioration of the display quality due to the defects of the main and redundancy light-emitting elements ED.

For example, the first-first light-emitting element 130a, second-first light-emitting element 140a, and third-first light-emitting element 150a transferred to one pixel PX may be used as the main light-emitting elements ED, and the first-second light-emitting element 130b, second-second light-emitting element 140b, and third-second light-emitting element 150b may be used as the redundancy light-emitting elements ED.

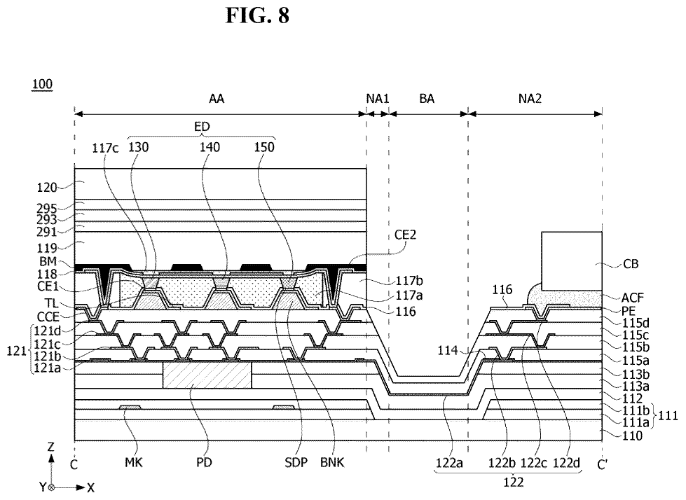

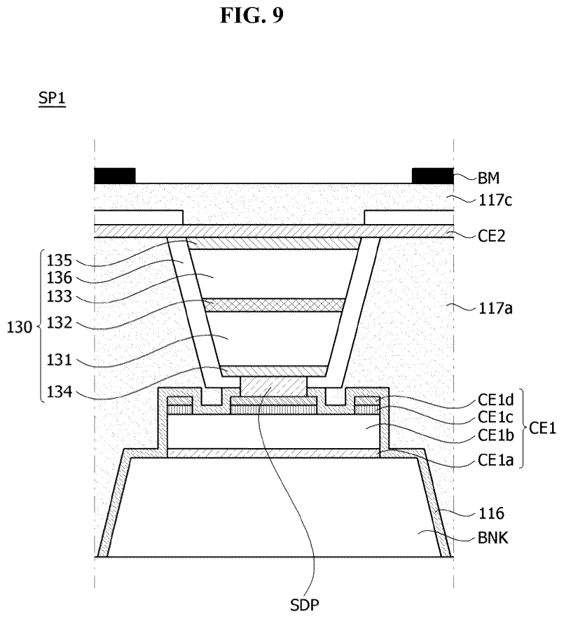

FIG. 8 is a cross-sectional view of the display device according to an embodiment of the present disclosure. FIG. 9 is a cross-sectional view illustrating the display device according to an embodiment of the present disclosure. For example, FIG. 9 is a cross-sectional view of the display area AA, the first non-display area NA1, the bending area BA, and the second non-display area NA2.

As illustrated in FIG. 8, a first buffer layer 111a and a second buffer layer 111b may be arranged on the remaining areas of the substrate 110 except for the bending area BA.

The first buffer layer 111a and the second buffer layer 111b may be arranged in the display area AA, the first non-display area NA1, and the second non-display area NA2. The first buffer layer 111a and the second buffer layer 111b may reduce the penetration of moisture or impurities through the substrate 110. The first buffer layer 111a and the second buffer layer 111b may be made of an inorganic insulating material. For example, the first buffer layer 111a and the second buffer layer 111b may be formed of a single layer or a multi-layer of silicon oxide (SiOx) or silicon nitride (SiNx), but embodiments of the present disclosure are not limited thereto.

For example, portions of the first buffer layer 111a and the second buffer layer 111b on the bending area BA may be removed. The top surface of the substrate 110 located in the bending area BA may be exposed from the first buffer layer 111a and the second buffer layer 111b. By removing the first buffer layer 111a and the second buffer layer 111b, that are made of an inorganic insulating material, from the bending area BA, cracking of the first buffer layer 111a and the second buffer layer 111b that may occur during bending may be minimized or at least reduced.

A plurality of alignment keys MK may be positioned between the first buffer layer 111a and the second buffer layer 111b. The plurality of alignment keys MK may be configured to identify the position of the pixel driving circuit PD during the manufacturing process of the display device 1000. For example, a plurality of alignment keys MK may be configured to align the position of the pixel driving circuit PD that is transferred onto the adhesive layer 112. In another example, the plurality of alignment keys MK may be omitted.

An adhesive layer 112 may be arranged on the second buffer layer 111b. The adhesive layer 112 may be arranged in the display area AA and the first non-display area NA1, the bending area BA, and the second non-display area NA2. For another example, at least a portion of the adhesive layer 112 may be removed from the non-display area NA that includes the bending area BA. For example, the adhesive layer 112 may be made of any of a polymer, epoxy resin, UV curable resin, polyimide-based, acrylate-based, urethane-based, and polydimethylsiloxane (PDMS), but embodiments of the present disclosure are not limited thereto.

In the display area AA, the pixel driving circuit PD may be arranged on the adhesive layer 112. If the pixel driving circuit PD is implemented as a drive driver, the drive driver may be mounted on the adhesive layer 112 by a transfer process, but embodiments of the present disclosure are not limited thereto.

A first protective layer 113a and a second protective layer 113b may be arranged on the adhesive layer 112 and the pixel driving circuit PD. The first protective layer 113a and the second protective layer 113b may be arranged to surround the side surfaces of the pixel driving circuit PD, but embodiments of the present disclosure are not limited thereto. For example, the second protective layer 113b may be arranged to cover at least a portion of the top surface of the pixel driving circuit PD. For example, at least one of the first protective layer 113a and the second protective layer 113b arranged on the bending area BA may be omitted. For example, the first protective layer 113a may be arranged entirely in the display area AA and the non-display area NA, and the second protective layer 113b may be arranged partially in the display area AA, the first non-display area NA1, and the second non-display area NA2. For example, a portion of the second protective layer 113b in the bending area BA may be removed. However, embodiments of the present disclosure are not limited thereto.

The first protective layer 113a and the second protective layer 113b may be formed of an organic insulating material, but embodiments of the present disclosure are not limited thereto. For example, the first protective layer 113a and the second protective layer 113b may be formed of a photo resist, polyimide (PI), or photo acryl-based material, but embodiments of the present disclosure are not limited thereto. For example, the first protective layer 113a and the second protective layer 113b may be an overcoating layer or an insulating layer, but embodiments of this disclosure are not limited thereto.

According to the present disclosure, the plurality of first connection wires 121 may be arranged on the second protective layer 113b in the display area AA. The plurality of first connection wires 121 may be wires for electrically connecting the pixel driving circuit PD to other components. For example, the pixel driving circuit PD may be electrically connected through the plurality of first connection wires 121 to the plurality of signal wires TL and the plurality of contact electrodes CCE, and the like. For example, the plurality of first connection wires 121 may include a first-first connection wire 121a, a first-second connection wire 121b, a first-third connection wire 121c, and a first-fourth connection wire 121d, but embodiments of the present disclosure are not limited thereto.

For example, a plurality of first-first connection wire 121a may be arranged on the second protective layer 113b. The plurality of first-first connection wires 121a may be electrically connected to the pixel driving circuit PD. The plurality of first-first connection wires 121a may transmit the voltage output from the pixel driving circuit PD to the first electrode CE1 or the second electrode CE2.

For example, a third protective layer 114 may be arranged on the second protective layer 113b. The third protective layer 114 may be entirely arranged in the display area AA and the non-display area NA. In the bending area BA, the third protective layer 114 may cover the side surface of the second protective layer 113b and the top surface of the first protective layer 113a. The third protective layer 114 may be formed of an organic insulating material. For example, the third protective layer 114 may be formed of a photo resist, polyimide (PI), or photo acryl-based material, but embodiments of the present disclosure are not limited thereto. For example, the first protective layer 113a, the second protective layer 113b, and the third protective layer 114 may be formed of the same material, but embodiments of the present disclosure are not limited thereto. Embodiments of the present disclosure are not limited to those described above.

The plurality of first-second connection wires 121b may be arranged on the third protective layer 114. The plurality of first-second connection wires 121b may be connected to or directly connected to the pixel driving circuit PD. For example, some of the first-second connection wires 121b may be directly connected to the pixel driving circuit PD through contact holes in the third protective layer 114. The other of the first-second connection wires 121b may be electrically connected to the first-first connection wire 121a through the contact holes in the third protective layer 114. However, embodiments of the present disclosure are not limited thereto. The voltage output from the pixel driving circuit PD may be transmitted to the first electrode CE1 or the second electrode CE2 through connection wires other than the plurality of first-second connection wires 121b.

A first insulating layer 115a may be formed on the plurality of first-second connection wires 121b. The first insulating layer 115a may be entirely arranged in the display area AA and the non-display area NA, but embodiments of the present disclosure are not limited thereto. The first insulating layer 115a may be formed of an organic insulating material, but embodiments of the present disclosure are not limited thereto. For example, the first insulating layer 115a may be formed of a photo resist, polyimide (PI), or photo acryl-based material, but embodiments of the present disclosure are not limited thereto.

The plurality of first-third connection wires 121c may be arranged on the first insulating layer 115a. The first-third connection wires 121c may be electrically connected to the plurality of first-second connection wire 121b. For example, the first-third connection wires 121c may be electrically connected to the first-second connection wires 121b through contact holes of the first insulating layer 115a.

A second insulating layer 115b may be arranged on the plurality of first-third connection wires 121c. The second insulating layer 115b may be arranged in the remaining area except for the bending area BA, but embodiments of the present disclosure are not limited thereto. The second insulating layer 115b may be arranged in the display area AA, the first non-display area NA1, and the second non-display area NA2, but embodiments of the present disclosure are not limited thereto. For example, a portion of the second protective layer 115b in the bending area BA may be removed. The second insulating layer 115b may be formed of an organic insulating material, but embodiments of the present disclosure are not limited thereto. For example, the second insulating layer 115b may be formed of a photo resist, polyimide (PI), or photo acryl-based material, but embodiments of the present disclosure are not limited thereto.

The plurality of first-fourth connection wires 121d may be arranged on the second insulating layer 115b. The plurality of first-fourth connection wires 121d may be electrically connected to the plurality of first-third connection wires 121c. For example, the first-fourth connection wires 121d may be electrically connected to the first-third connection wires 121c via contact holes of the second insulating layer 115b.

According to examples of the present disclosure, the plurality of second connection wires 122 may be arranged on the second protective layer 113b in the display area NA. The plurality of second connection wires 122 may be wires for transmitting signals, that are transmitted from the flexible circuit board (or flexible film) CB and the printed circuit board (160 in FIG. 1) to the pad part PAD, to the pixel driving circuit PD of the display area AA. For example, the plurality of second connection wires 122 may be electrically connected to the plurality of pad electrodes PE to receive signals from the flexible circuit board (or flexible film) CB and the printed circuit board.

For example, the plurality of second connection wires 122 may extend from the pad part PAD toward the display area AA to transmit signals to the wires in the display area AA. In this case, the plurality of second connection wires 122 may function as the link wires LL. The plurality of second connection wires 122 may include a second-first connection wire 122a, a second-second connection wire 122b, a second-third connection wire 122c, and a second-fourth connection wire 122d.

The plurality of second-first connection wires 122a may be arranged on the second protective layer 113b. The plurality of second-first connection wires 122a may extend from the second non-display area NA2 to the bending area BA and the first non-display area NA1. The plurality of second-first connection wire 122a may transmit signals, that has been transmitted from the flexible circuit board (or flexible film) CB and the printed circuit board to the pad part PAD, to the pixel driving circuit PD of the display area AA.

The plurality of first-second connection wires 122b may be arranged on the third protective layer 114. The plurality of second-second connection wires 122b may be arranged on the second non-display area NA2. The second-second connection wires 122b may be electrically connected to the second-first connection wires 122a through contact holes in the third protective layer 114. Thus, the signals from the flexible circuit board (or flexible film) (CB) and the printed circuit board may be transmitted to the second-first connection wires 122a through the second-second connection wires 122b.

The plurality of second-third connection wires 122c may be arranged on the first insulating layer 115a. The second-third connection wires 122c may be arranged in the second non-display area NA2. The second-third connection wires 122c may be electrically connected to the second-second connection wires 122b through contact holes in the first insulating layer 115a. Thus, the signals from the flexible circuit board (or flexible film) (CB) and the printed circuit board may be transmitted to the second-first connection wires 122a through the second-third connection wires 122c and the second-second connection wires 122b.

The plurality of second-fourth connection wires 122d may be arranged on the second insulating layer 115b. The second-fourth connection wires 122d may be arranged in the second non-display area NA2. The second-fourth connection wires 122d may be electrically connected to the second-third connection wires 122c through contact holes in the second insulating layer 115b. Thus, the signals from the flexible film (FF) and the printed circuit board may be transmitted to the second-first connection wires 122a through the second-fourth connection wires 122d, the second-third connection wires 122c, and the second-second connection wire 122b.

The plurality of first connection wires 121 and the plurality of second connection wires 122 may be formed of any one of a conductive material having excellent ductility or various conductive materials used in the display area AA. For example, the second connection wire 122, a portion of which is arranged in the bending area BA, may be made of a conductive material having excellent ductility, such as gold (Au), silver (Ag), or aluminum (Al), but embodiments of the present disclosure are not limited thereto. For another example, the plurality of first connection wires 121 and the plurality of second connection wires 122 may be formed of molybdenum (Mo), chromium (Cr), titanium (Ti), nickel (Ni), neodymium (Nd), copper (Cu), and alloys of silver (Ag) and magnesium (Mg), or alloys thereof, but embodiments of the present disclosure are not limited thereto.

A third insulating layer 115c may be arranged on the plurality of first connection wires 121 and the plurality of second connection wires 122. The third insulating layer 115c may be arranged in the remaining area except for the bending area BA, but embodiments of the present disclosure are not limited thereto. The third insulating layer 115c may be arranged in the display area AA, the first non-display area NA1, and the second non-display area NA2. A portion of the third insulating layer 115c in the bending area BA may be removed. The third insulating layer 115c may be formed of an organic insulating material, but embodiments of the present disclosure are not limited thereto. For example, the third insulating layer 115c may be formed of a photo resist, polyimide (PI), or photo acryl-based material, but embodiments of the present disclosure are not limited thereto.

In the display area AA, the plurality of banks BNK may be arranged on the third insulating layer 115c. The plurality of banks BNK may be arranged to overlap each of the plurality of sub-pixels. One or more light-emitting elements ED of the same type may be arranged in the upper portion of each of the plurality of banks BNK.

In the display area AA, the plurality of signal wires TL may be arranged on the third insulating layer 115c. The plurality of signal wires TL may be arranged in an area between the plurality of banks BNK. For example, the plurality of signal wires TL may be arranged adjacent to any one of the plurality of banks BNK.

The plurality of contact electrodes CCE may be arranged on the third insulating layer 115c in the display area AA. The plurality of contact electrodes CCE may supply the cathode voltage from the pixel driving circuit PD to the second electrode CE2.

The first electrode CE1 may be arranged on the bank BNK. For example, the first electrode CE1 may be arranged extending from the adjacent signal wire TL toward the upper portion of the bank BNK. The first electrode CE1 may be arranged on the top surface of the bank BNK and the side surface of the bank BNK. For example, the first electrode CE1 may be arranged extending from the signal wire TL on the top surface of the third insulating layer 115c to the side surface of the bank BNK and to the top surface of the bank BNK.

With reference to FIGS. 9, the first electrode CE1 may be composed of a plurality of conductive layers. For example, the first electrode CE1 may include a first conductive layer Ce1a, a second conductive layer CE1b, a third conductive layer Ce1c, and a fourth conductive layer CE1d, but embodiments of the present disclosure are not limited thereto.

The first conductive layer CE1a may be arranged on the bank BNK. The second conductive layer CE1b may be arranged on the first conductive layer CE1a. The third conductive layer CE1c may be arranged on the second conductive layer CE1b. The fourth conductive layer CE1d may be arranged on the third conductive layer CE1c. For example, each of the first conductive layer CE1a, second conductive layer CE1b, third conductive layer CE1c, and fourth conductive layer CE1d may be formed of Titanium (Ti), Molybdenum (Mo), Aluminum (Al), or Titanium (Ti) and Indium Tin Oxide (ITO), but embodiments of the present disclosure are not limited thereto.

According to example embodiments the present disclosure, some of the plurality of conductive layers constituting the first electrode CE1 and having good reflection efficiency may be configured as alignment keys and/or reflectors for aligning the light-emitting element ED. For example, the second conductive layer CE1b of the plurality of conductive layers of the first electrode CE1 may include a reflective material. For example, the second conductive layer CE1b may include aluminum (Al), but embodiments of the present disclosure are not limited thereto. In this way, the second conductive layer CE1b may be configured as a reflector. Further, the high reflective efficiency of the second conductive layer CE1b may facilitate easy identification during the manufacturing process, allowing for alignment of the light-emitting element ED or its transfer position relative to the second conductive layer CE1b.

For example, to configure the second conductive layer CE1b as a reflector, the third conductive layer CE1c and the fourth conductive layer CE1d covering the second conductive layer CE1b may be partially removed or etched away. For example, portions of the third conductive layer CE1c and fourth conductive layer CE1d arranged on the bank BNK may be partially removed or etched to expose the top surface of the second conductive layer CE1b. For example, the third conductive layer CE1c and the fourth conductive layer CE1d, except for the center portion and the border portions (or edge portions) of these layers where a solder pattern SDP is placed, may be removed. For example, the border portion (or edge portion) of each of the third conductive layer CE1c made of titanium (Ti), and the fourth conductive layer CE1d made of indium tin oxide (ITO) may not be etched. Accordingly, the other conductive layers of the first electrode CE1 may be prevented from being corroded by the TMAH (TetraMethylAmmoniumHydroxide) solution used in the masking process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), that has good adhesion to the solder pattern SDP and has corrosion resistance and acid resistance. However, embodiments of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process, but embodiments of the present disclosure are not limited thereto.

According to the present disclosure, the signal wire TL, the contact electrode CCE, and the pad electrode PE arranged in the same layer as the first electrode CE1 may be formed of a multi-layer of a conductive material, but embodiments of the present disclosure are not limited thereto. For example, the signal wire TL, the contact electrode CCE, and the pad electrode PE may be made of a multi-layer of indium tin oxide (ITO)/titanium (Ti)/aluminum (Al)/titanium (Ti), but embodiments of the present disclosure are not limited thereto.

According to the present disclosure, the solder pattern SDP may be arranged on the first electrode CE1 in each of the plurality of sub-pixels. The solder pattern SDP may bond the light-emitting element ED to the first electrode CE1. The first electrode CE1 and the light-emitting element ED may be electrically connected each other through eutectic bonding using the solder pattern SDP, but embodiments of the present disclosure are not limited thereto. For example, the first electrode CE1 and the anode electrode 134 of the light-emitting element ED may be electrically connected by the solder pattern SDP through eutectic bonding, but embodiments of the present disclosure are not limited thereto. For example, if the solder pattern SDP is formed of indium (In) and the anode electrode 134 of the light-emitting element ED is formed of gold (Au), the solder pattern SDP and the anode electrode 134 may be bonded by applying heat and pressure during the transfer process of the light-emitting element ED. The eutectic bonding may allow the light-emitting element ED to be bonded to the solder pattern SDP and the first electrode CE1 without a separate adhesives. For example, the solder pattern SDP may be formed of indium (In), tin (Sn), or an alloy thereof, but embodiments of the present disclosure are not limited thereto. For example, the solder pattern SDP may be a bonding pad, or a binding pad, but embodiments of the present disclosure are not limited thereto.

According to examples of the present disclosure, a passivation layer 116 may be arranged on the plurality of signal wires TL, the plurality of first electrodes CE1, the plurality of contact electrodes CCE, and the third insulating layer 115c. For example, the passivation layer 116 may be arranged in the display area AA, the first non-display area NA1, and the second non-display area NA2. A portion of the passivation layer 116 arranged in the bending area BA may be removed. A portion of the passivation layer 116 covering the plurality of pad electrodes PE in the second non-display area NA2 may be removed. The passivation layer 116 may be arranged to cover the remaining areas except the area in which the bending area BA, the plurality of pad electrodes PE, and the solder pattern SDP are arranged, thereby reducing moisture or impurities to penetrate into the light-emitting element ED. For example, the passivation layer 116 may be formed of a single or multiple layers of silicon oxide (SiOx) or silicon nitride (SiNx), but embodiments of the present disclosure are not limited thereto. For example, the passivation layer 116 may be a protective layer, an insulating layer, or the like, but embodiments of the present disclosure are not limited thereto. For example, the passivation layer 116 may include a hole that expose the solder pattern SDP.

The light-emitting element ED may be arranged on the solder pattern SDP in each of the plurality of sub-pixels. The first light-emitting element 130 may be arranged in the first sub-pixel SP1. The second light-emitting element 140 may be arranged in the second sub-pixel SP2. The third light-emitting element 150 may be arranged in the third sub-pixel SP3.

The light-emitting element ED may be formed on a silicon wafer by a method, such as metal organic vapor deposition (MOCVD), chemical vapor deposition (CVD), plasma-enhanced chemical vapor deposition (PECVD), molecular beam growth (MBE), hydride vapor deposition (HVPE), or sputtering, but embodiments of the present disclosure are not limited thereto.

With reference to FIG. 9, the first light-emitting element 130 may include the anode electrode 134, a first semiconductor layer 131, an active layer 132, a second semiconductor layer 133, the cathode electrode 135, and an encapsulation film 136, but embodiments of the present disclosure are not limited thereto. For example, the encapsulation film 136 may not be included in the first light-emitting element 130.

The first semiconductor layer 131 may be arranged on the solder pattern SDP. The second semiconductor layer 133 may be arranged on the first semiconductor layer 131. For example, one of the first semiconductor layer 131 and the second semiconductor layer 133 may be implemented as a compound semiconductor, such as a III-V group, II-VI group, or the like, and may be doped with impurities (or dopants). For example, one of the first semiconductor layer 131 and the second semiconductor layer 133 may be a semiconductor layer doped with n-type impurities, and the other may be a semiconductor layer doped with p-type impurities, but embodiments of the present disclosure are not limited thereto. For example, one or more of the first semiconductor layer 131 and the second semiconductor layer 133 may be a layer doped with n-type or p-type impurities on a material, such as gallium nitride (GaN), gallium phosphide (GaP), aluminum gallium indium phosphide (AlGaInP), indium gallium nitride (AlGaN), aluminum indium nitride (AlInN), aluminum gallium nitride (AlInGaN), aluminum gallium gallium nitride (AlGaAs), aluminum gallium arsenide (AlGaAs), or gallium arsenide (GaAs), but embodiments of the present disclosure are not limited thereto. For example, the n-type impurity may be silicon (Si), germanium (Ge), selenium (Se), carbon (C), tellurium (Te), or tin (Sn), but embodiments of the present disclosure are not limited thereto. For example, the p-type impurity may be magnesium (Mg), zinc (Zn), calcium (Ca), strontium (Sr), barium (Ba), or beryllium (Be), but embodiments of the present disclosure are not limited thereto.

For example, the first semiconductor layer 131 and the second semiconductor layer 133 may be a nitride semiconductor containing n-type impurities and a nitride semiconductor containing p-type impurities, respectively, but embodiments of the present disclosure are not limited thereto. For example, the first semiconductor layer 131 may be a nitride semiconductor containing p-type impurities, and the second semiconductor layer 133 may be a nitride semiconductor containing n-type impurities, but embodiments of the present disclosure are not limited thereto.

The active layer 132 may be arranged between the first semiconductor layer 131 and the second semiconductor layer 133. The active layer 132 may emit light by receiving holes and electrons from the first semiconductor layer 131 and the second semiconductor layer 133. For example, the active layer 132 may be composed of one of a single well structure, a multi-well structure, a single quantum well structure, a multi-quantum well (MQW) structure, a quantum dot structure, and a quantum line structure, but embodiments of the present disclosure are not limited thereto. For example, the active layer 132 may ba formed of indium gallium nitride (InGaN) or gallium nitride (GaN), but embodiments of the present disclosure are not limited thereto.

For another example, the active layer 132 may include a multi quantum well (MQW) structure having a well layer and a barrier layer with a higher band gap than the well layer. For example, the active layer 132 may be formed of InGaN as a well layer and AlGaN layer as a barrier layer, but embodiments of the present disclosure are not limited thereto.

The anode electrode 134 may be arranged between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal wire TL, the first electrode CE1, and the anode electrode 134. For example, the anode electrode 134 may be formed of a conductive material that is eutectically bondable with the solder pattern SDP, but embodiments of the present disclosure are not limited thereto. For example, the anode electrode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or alloys thereof, but embodiments of the present disclosure are not limited thereto.

The cathode electrode 135 may be arranged on the second semiconductor layer 133. For example, the cathode electrode 135 may electrically connect the second semiconductor layer 133 and the second electrode CE2. The cathode voltage output from the pixel driving circuit PD may be applied to the second semiconductor layer 133 through the contact electrode CCE, the second electrode CE2, and the cathode electrode 135. The cathode electrode 135 may be formed of a transparent conductive material to allow light emitted from the ED to be directed to the upper portion of the ED, but embodiments of the present disclosure are not limited thereto. For example, the cathode electrode 135 may be formed of a material, such as Indium Tin Oxide (ITO), Indium Zinc Oxide (IZO), or Indium Gallium Zinc Oxide (IGZO), but embodiments of the present disclosure are not limited thereto.

The encapsulation film 136 may be arranged on at least a portion of the first semiconductor layer 131, the active layer 132, the second semiconductor layer 133, the anode electrode 134, and the cathode electrode 135. For example, the encapsulation film 136 may surround at least a portion of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be arranged on a side surface of the first semiconductor layer 131, a side surface of the active layer 132, and a side surface of the second semiconductor layer 133.

For example, the encapsulation film 136 may be arranged on at least portions of the anode electrode 134 and the cathode electrode 135, such as an edge portion (or one side) of the anode electrode 134 and an edge portion (or one side) of the cathode electrode 135. At least a portion of the anode electrode 134 may be exposed from the encapsulation film 136, allowing the anode electrode 134 and the solder pattern SDP to be connected. For example, at least a portion of the cathode electrode 135 may be exposed from the encapsulation film 136, allowing the cathode electrode 135 and the second electrode CE2 to be connected. For example, the encapsulation layer 136 may be formed of an insulating material, such as silicon nitride (SiNx) or silicon oxide (SiOx), but embodiments of the present disclosure are not limited thereto.

For another example, the encapsulation film 136 may have a structure in which a reflective material is dispersed in a resin layer, but embodiments of the present disclosure are not limited thereto. For example, the encapsulation film 136 may be fabricated as a reflector having various structures, but embodiments of the present disclosure are not limited thereto. Light exciting from the active layer 132 by the encapsulation layer 136 is reflected upward to improve light extraction efficiency. For example, the encapsulation layer 136 may be a reflective layer, but embodiments of the present disclosure are not limited thereto.

Although the light-emitting element ED is described herein as having a vertical structure, embodiments of the present disclosure are not limited thereto. For example, the light-emitting element ED may have a lateral structure or a flip chip structure.

While the first light-emitting element 130 has been described with reference to FIG. 9, the second light-emitting element 140 and third light-emitting element 150 may have substantially the same structure as the first light-emitting element 130. For example, the second light-emitting element 140 and the third light-emitting element 150 may be substantially the same as the first light-emitting element 130 having the first semiconductor layer 131, the active layer 132, the second semiconductor layer 133, the anode electrode 134, the cathode electrode 135, and the encapsulating film 136.

According to example embodiments of the present disclosure, a first optical layer 117a may be arranged surrounding a plurality of light-emitting elements ED in the display area AA. For example, the first optical layer 117a may be arranged to cover the plurality of light-emitting elements ED and the banks BNK in a plurality of sub-pixel areas. For example, the first optical layer 117a may cover between the bank BNK, a portion of the passivation layer 116, and the plurality of light-emitting elements ED. The first optical layer 117a may be arranged between or cover the plurality of light-emitting elements ED included in one pixel PX, and between the plurality of banks BNK. For example, the first optical layer 117a may extend in the first direction (X-axis direction), and may be spaced apart from the second direction (Y-axis direction). For example, the first optical layer 117a may be arranged between the passivation layer 116 and the second electrode CE2 to surround the side portions of the light-emitting element ED and the bank BNK, but embodiments of the present disclosure are not limited thereto. For example, the first optical layer 117a may be a diffusion layer, a sidewall diffusion layer, or the like, but embodiments of the present disclosure are not limited thereto.

The first optical layer 117a may include an organic insulating material in which fine particles are dispersed, but embodiments of the present disclosure are not limited thereto. For example, the first optical layer 117a may be formed of siloxane in which fine metal particles, such as titanium dioxide (TiO₂) particles are dispersed, but embodiments of the present disclosure are not limited thereto. Light from the plurality of light-emitting elements ED may be scattered by the fine particles dispersed in the first optical layer 117a and emitted to the outside of the display device 1000. This may ensure that the first optical layer 117a improves the extraction efficiency of light emitted from the plurality of light-emitting elements ED.

For example, the first optical layer 117a may be arranged in each of the plurality of pixels PX, or may be arranged together in some of the pixels PX arranged in the same row, but embodiments of the present disclosure are not limited thereto. For example, the first optical layer 117a may be arranged in each of the plurality of pixels PX, or one first optical layer 117a may be shared by the plurality of pixels PX. For another example, each of the plurality of sub-pixels may separately include the first optical layer 117a, but embodiments of the present disclosure are not limited thereto.

The second optical layer 117b may be arranged on the passivation layer 116 in the display area AA. For example, the second optical layer 117b may be arranged to surround the first optical layer 117a. For example, the second optical layer 117b may abut the side surface of the first optical layer 117a. For example, the second optical layer 117b may be arranged in an area between the plurality of pixels PX. However, embodiments of the present disclosure are not limited thereto. For example, the second optical layer 117b may be a diffusion layer, a diffusion layer window, or a window diffusion layer, but embodiments of the present disclosure are not limited thereto.

The second optical layer 117b may be formed of an organic insulating material, but embodiments of the present disclosure are not limited thereto. The second optical layer 117b may be formed of the same material as the first optical layer 117a, but embodiments of the present disclosure are not limited thereto. For example, the first optical layer 117a may include fine particles, and the second optical layer 117b may not include fine particles. For example, the second optical layer 117b may be made of siloxane, but embodiments of the present disclosure are not limited thereto.

For example, the thickness of the first optical layer 117a may be less than the thickness of the second optical layer 117b, but embodiments of the present disclosure are not limited thereto. Accordingly, when viewed from a plan, the area in which the first optical layer 117a is arranged may include a concave portion recessed inwardly from the upper surface of the second optical layer 117b.

The second electrode CE2 may be arranged on the first optical layer 117a and the second optical layer 117b. For example, the second electrode CE2 may be electrically connected to the plurality of contact electrodes CCE through contact holes in the second optical layer 117b. For example, the second electrode CE2 may be arranged on the plurality of light-emitting elements ED. For example, the second electrode CE2 may include a transparent conductive oxide, such as indium tin oxide (ITO) or indium zinc oxide (IZO), but embodiments of the present disclosure are not limited thereto. For example, the second electrode CE2 may be arranged in contact with a cathode electrode 135. For example, the second electrode CE2 may overlap the first optical layer 117a. For example, the second electrode CE2 may cover the outer plane of the first optical layer 117a.

The second electrode CE2 may extend continuously in a first direction (X-axis direction) of the substrate 110. Accordingly, it may be commonly connected to the plurality of pixels PX arranged in the first direction (X-axis direction) of the substrate 110. For example, the second electrode CE2 may be commonly connected to the plurality of pixels PX.

The second electrode CE2 may extend continuously on the first optical layer 117a, the second optical layer 117b, and the light-emitting element ED. The area in which the first optical layer 117a is arranged may include a concave portion that is recessed inwardly from the upper surface of the second optical layer 117b. Accordingly, the first portion of the second electrode CE2 arranged on the first optical layer 117a is arranged along the concave portion, so that it may be located at a lower position than the second portion of the second electrode CE2 arranged on the second optical layer 117b.

A third optical layer 117c may be arranged on the second electrode CE2. The third optical layer 117c may be arranged to overlap the plurality of light-emitting elements ED and the first optical layer 117a. The third optical layer 117c may be arranged on the upper portion of the second electrode CE2 and the plurality of light-emitting elements ED, thereby improving the mura that may occur in some of the plurality of light-emitting elements ED. For example, when the plurality of light-emitting elements ED are transferred to the substrate 110 of the display device 1000, areas having non-uniform spacing between the plurality of light-emitting elements ED may occur due to process variations. If the spacing between the plurality of light-emitting elements ED is uneven, the emission areas of the plurality of light-emitting elements ED may be arranged uneven, resulting in the mura visible to the user. Because the third optical layer 117c may be formed to diffuse light uniformly onto over the plurality of light-emitting elements ED, it is possible to reduce the light emitted from some of the light-emitting elements ED from being visually recognized as the mura. Therefore, the light emitted from the plurality of light-emitting elements ED by the third optical layer 117c is uniformly diffused and extracted to the outside of the display device 1000, which may improve the luminance uniformity of the display device 1000.

The third optical layer 117c may be formed of an organic insulating material in which fine particles are dispersed, but embodiments of the present disclosure are not limited thereto. For example, the third optical layer 117c may be formed of siloxane dispersed with fine metal particles, such as titanium dioxide (TiO₃) particles, but embodiments of the present disclosure are not limited thereto. For example, the third optical layer 117c may be formed of the same material as the first optical layer 117a, but embodiments of the present disclosure are not limited thereto. For example, the third optical layer 117c may be a diffusion layer, a top surface diffusion layer, or the like, but embodiments of the present disclosure are not limited thereto.

Light from the plurality of light-emitting elements ED may be scattered by fine particles dispersed in the third optical layer 117c and emitted to the outside of the display device 1000. The third optical layer 117c may further improve luminance uniformity of the display device 1000 by uniformly mixing light emitted from the plurality of light-emitting elements ED. Further, light scattered from the plurality of fine particles may improve the light extraction efficiency of the display device 1000, thereby enabling the display device 1000 to be driven at low power.

A black matrix BM may be arranged on the second electrode CE2, the first optical layer 117a, the third optical layer 117b, and the second optical layer 117c in the display area AA. For example, the black matrix BM may fill the contact holes in the second optical layer 117b. The black matrix BM may be configured to cover the display area AA, thereby reducing the color mixing of light from the plurality of sub-pixels and reflection of external light. For example, the black matrix BM may also be arranged within the contact holes in which the second electrode CE2 and the contact electrode CCE are connected, which may prevent light leakage between the plurality of adjacent sub-pixels.

For example, the black matrix BM may be formed of an opaque material, but embodiments of the present disclosure are not limited thereto. For example, the black matrix BM may be a black pigment or an organic insulating material to which a black dye has been added, but embodiments of the present disclosure are not limited thereto.

In the display area AA, a cover layer 118 may be arranged on the black matrix BM. The cover layer 118 may protect the configuration under the cover layer 118. For example, the cover layer 118 may be formed of an organic insulating material, but embodiments of the present disclosure are not limited thereto. For example, the cover layer 118 may be formed of a photo resist, polyimide (PI), or photo acryl-based material, but embodiments of the present disclosure are not limited thereto. For example, the cover layer 118 may be an overcoating layer or an insulating layer, but embodiments of the present disclosure are not limited thereto.

The polarizing layer 293 may be arranged on the cover layer 118 through the first adhesive layer 291. The cover member 120 may be arranged on the polarizing layer 293 through the second adhesive layer 295. For example, the first adhesive layer 291 and the second adhesive layer 295 may include an optically clear adhesive (OCA), an optically clear resin (OCR), or a pressure sensitive adhesive (PSA), but embodiments of the present disclosure are not limited thereto.

The plurality of pad electrodes PE may be arranged on the third insulating layer 115c in the second non-display area NA2. For example, at least a portion of the plurality of pad electrodes PE may be exposed from the passivation layer 116. For example, the plurality of pad electrodes PE may be electrically connected to the second-fourth connection wires 122d through contact holes in the third insulating layer 115c.

An adhesive layer ACF may be arranged on the plurality of pad electrode PE. The adhesive layer ACF may be an adhesive layer in which conductive balls are dispersed in an insulating material, but embodiments of the present disclosure are not limited thereto. When heat or pressure is applied to the adhesive layer ACF, the conductive balls may become electrically connected and have conductive properties at the points where heat or pressure is applied, exhibiting the conductive properties. The adhesive layer ACF may be arranged between the plurality of pad electrodes PE and the flexible circuit board (or flexible film) CB to attach or bond the flexible circuit board (or flexible film) CB to the plurality of pad electrodes PE. For example, the adhesive layer ACF may be an anisotropic conductive film (ACF), but embodiments of the present disclosure are not limited thereto.

The flexible circuit board (or flexible film) CB may be arranged on the adhesive layer ACF. The flexible circuit board (or flexible film) CB may be electrically connected to the plurality of pad electrodes PE through the adhesive layer ACF. Thus, signals output from the flexible circuit board (or flexible film) CB and the printed circuit board may be transmitted to the pixel driving circuit PD of the display area AA through the plurality of pad electrodes PE, the second-fourth connection wire 122d, the second-third connection wire 122c, the second-second connection wire 122b, and the second-first connection wire 122a.

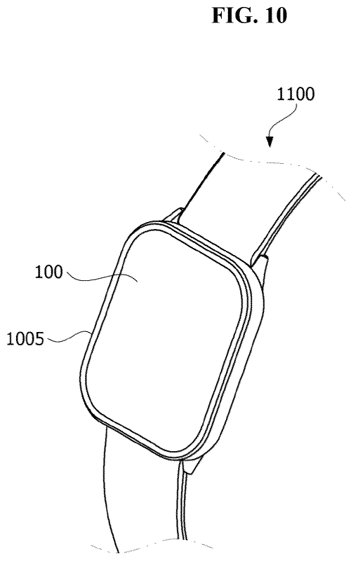

FIGS. 10 to 13 are diagrams illustrating an apparatus to which the display device according to embodiments of the present disclosure is applied.

As shown in FIGS. 10 to 13, the display device 1000 may be included in a variety of devices or electronics. For example, various electronic devices may include a wearable device 1100, a mobile device 1200, a laptop 1300, and a monitor or television (TV) 1400, but embodiments of the present disclosure are not limited thereto.

The wearable device 1100, the mobile device 1200, the laptop computer 1300, and the monitor or TV 1400 may include their respective case parts 1005, 1010, 1015, and 1020, and the display panel 100 and the display device 1000 according to the embodiments described above. The display device according to an example embodiment of the present disclosure may include a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation, an in-vehicle display device, an in-theater display device, a television, a wallpaper device, a signage device, a gaming device, a laptop, a monitor, a camera, a camcorder, and a main board of a consumer electronics device.

In the following, a test element and a method of fabricating the same according to an embodiment of the present disclosure will be described.

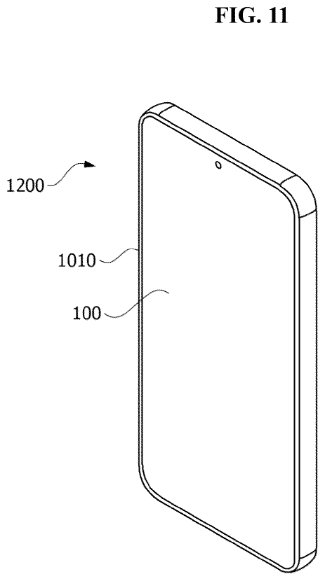

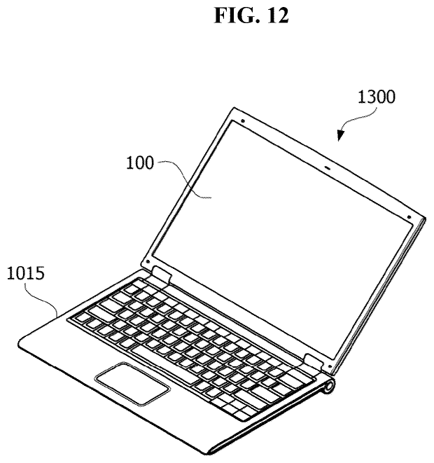

FIG. 14 is a plan view illustrating a semiconductor device according to an embodiment of the present disclosure, and FIG. 15 is an enlarged view of an area A of FIG. 14.

A semiconductor device or a device 1 according to one embodiment of the present disclosure may include a plurality of chip areas CA in which integrated circuit chips are formed, and a partitioning area SL between the plurality of chip areas CA. The plurality of chip areas CA may be arranged along a plurality of rows and columns on the wafer, but embodiments of the present disclosure are not limited thereto.

Each of the plurality of chip areas CA may include an integrated circuit area and a dummy area. Within the integrated circuit area, semiconductor elements may be provided, and various circuit elements, such as resistors, capacitors, transistors, diodes, and the like may be formed. In one embodiment of the present disclosure, a semiconductor element may be a display device using micro-LEDs, but embodiments of the present disclosure are not limited thereto.

A plurality of semiconductor processes may be performed to form the semiconductor elements in the integrated circuit areas of the plurality of chip areas CA. If the semiconductor processes are not performed properly, defects, such as an opening or a short, may occur and the performance of the semiconductor elements (or inorganic light-emitting elements) may be deteriorated.

A plurality of test elements or a test element group (TEG) may be provided on the wafer to determine defects during the semiconductor processes of the integrated circuit areas. In an example embodiment, the test elements may be formed in test areas TA located within the partitioning area SL. In another embodiment, the test elements may be formed in the dummy area, in which no semiconductor elements or inorganic light-emitting elements are formed, within the plurality of chip areas CA. The dummy area may be an area other than the integrated circuit area (or the display area). Alternatively, the test elements may be placed in both the test areas TA within the partitioning area SL and the dummy area, but embodiments of the present disclosure are not limited thereto. The test elements placed in the dummy area may remain in the finally produced chips or display devices, while the test elements placed in the test areas TA within the partitioning area SL may not remain in the finally produced chips or display devices, but embodiments of the present disclosure are not limited thereto.

The test elements or the test element group may be formed simultaneously with the semiconductor elements or the inorganic light-emitting elements in the integrated circuit areas, but embodiments of the present disclosure are not limited thereto. By examining the electrical properties of the test element or the test element group during the manufacture of the semiconductor elements, it is possible to determine whether the semiconductor elements or the inorganic light-emitting elements are formed normally.

The partitioning area SL may be an area, such as a scribe lane, for separating a plurality of chip areas CA from each other by a scribing or trimming process, such as a scribe lane. The semiconductor elements or the inorganic light-emitting elements intended to be formed in the integrated circuit areas may not be placed in the partitioning area SL. In consideration of the efficiency and reliability of the scribing process, the partitioning area SL may be a plurality of straight lines between the plurality of chip areas CA arranged along a plurality of rows and columns, but embodiments of the present disclosure are not limited thereto.

The test areas TA may be areas in which test structures are formed for testing physical or electrical characteristics of various elements that constitute the semiconductor device 1 or the display device. For example, by testing the physical or electrical characteristics of the test elements or the test element group formed within the test areas TA, the reliability of the integrated circuits, such as the inorganic light-emitting elements, contained within the plurality of chip areas CA or the display area may be determined.

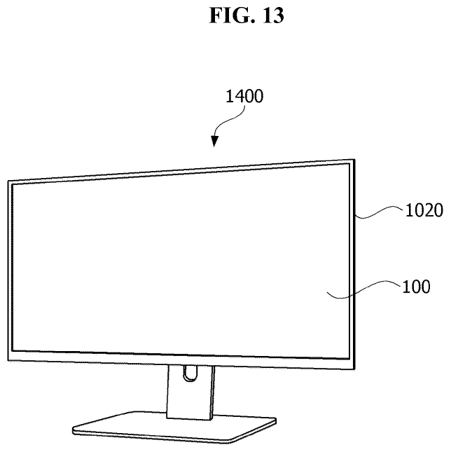

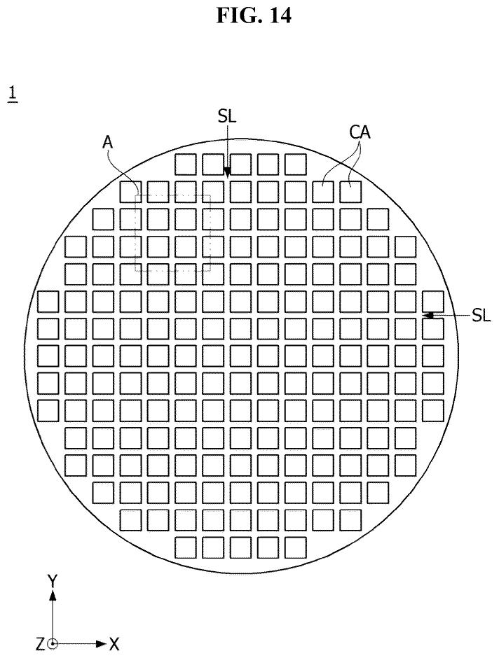

FIG. 16 is a cross-sectional view of illustrating an example of a test element in which contact resistance between the first and second layers is not measured, and FIG. 17 is a diagram illustrating an example mask pattern used to generate the test element of FIG. 16.

As shown in FIGS. 16 and 17, a test element or a test element group in which the contact resistance between the first layer L1 and the second layer L2 cannot be measured may be created, for example, as follows.

A first layer L1 may be formed on a base layer BL, and a photoresist layer PR may be formed on the first layer L1. A pattern is formed on the photoresist layer PR through an exposure process, and a second layer L2 may be formed or deposited on the photoresist layer PR having a patterned area PA. The patterned area PA thus formed has a reverse taper profile, as shown in FIG. 16, wherein, for example, the photoresist layer PR defining the patterned area PA has a sidewall of the reverse taper profile. Therefore, the second layer L2 is formed or deposited in a discontinuous state within the patterned area PA, making it impossible to measure the contact resistance between the first layer L1 and the second layer L2.

As an example of adjusting the taper angle of the patterned area PA, light may be irradiated onto the photoresist layer PR through a mask having a wing slit pattern as shown in FIG. 17 in an exposure process, thereby adjusting the amount of exposure. Because the continuity of the second layer L2 in the patterned area PA is not maintained even by the above method, the contact resistance between the first layer L1 and the second layer L2 may still not be measured.

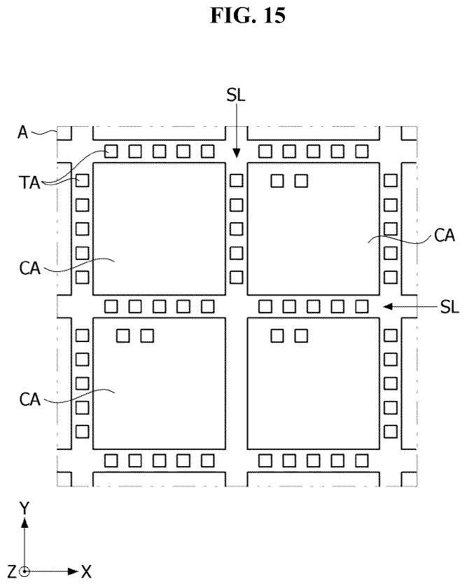

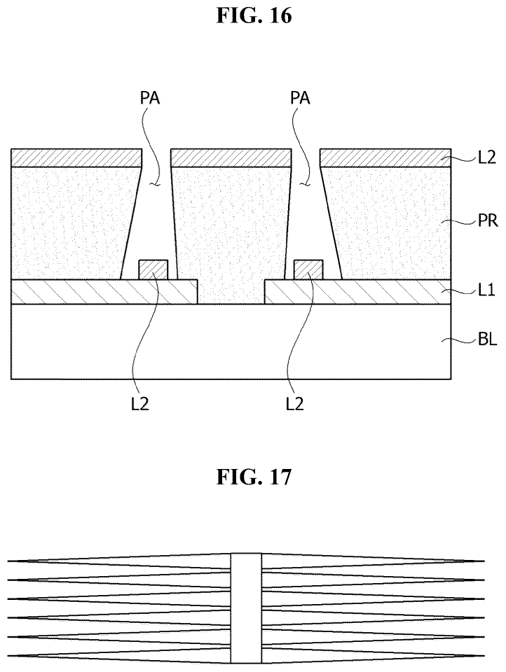

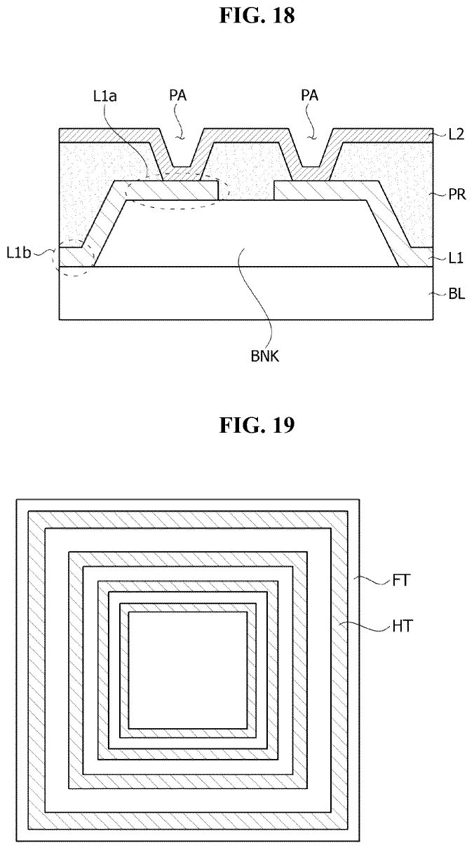

FIG. 18 is a cross-sectional view illustrating a test element or a test element group according to an embodiment of the present disclosure, FIG. 19 is a diagram illustrating a mask pattern forming the test element or the test element group of FIG. 18, and FIG. 20 is a plan view of the test element of FIG. 18.

With reference to FIG. 18, a method of fabricating a test element or a test element group according to one embodiment of the present disclosure is as follows.

A bank BNK may be formed on a base layer BL. A first layer L1 may be arranged on the base layer BL and it may be formed to cover the inclined side surfaces and top surface of the bank BNK. Thus, a first area L1a of the first layer L1 formed on the top surface of the bank BNK may be positioned at a higher position than a second area L1b of the first layer L1 formed on the base layer BL. For example, the first area L1a of the first layer L1 may be positioned as high as the height of the bank BNK relative to the second area L1b.

A photoresist layer PR is formed on the first layer L1 thus formed, and a pattern is formed on the photoresist layer PR through an exposure process so that a second layer L2 may be formed or deposited on the photoresist layer PR having the patterned area PA. For example, the patterned area PA may be constructed by a lift-off process.

To adjust the taper angle of the patterned area PA, the pattern may be formed by irradiating light to the photoresist layer PR through a mask including a full-tone (FT) slit and a half-tone (HT) slit, as shown in FIG. 19.

The patterned area PA thus formed has a positive taper profile, as shown in FIG. 18, wherein, for example, the photoresist layer PR defining the patterned area PA has a positive tapered sidewalls. As a result, the second layer L2 may be formed or deposited to maintain the continuity even in the patterned area PA, and the entirety of the second layer is connected through the patterned area PA, thereby enabling the contact resistance between the first layer L1 and the second layer L2 to be measured.

Even if the patterned area PA has a positive taper profile, if the depth of the patterned area PA is deep, the continuity of the second layer L2 may be broken during the formation or deposition of the second layer L2. In an example embodiment of the present disclosure, the bank BNK may be positioned under the first layer L1 to allow the first layer L1 and the second layer L2 to contact each other at a relatively high location (or point) so that the depth of the patterned area PA is reduced, thereby maintaining the continuity of the second layer L2 in the patterned area PA. In one embodiment, with reference to FIG. 20, the first layer L1 may be electrically connected to a pad PAD. Here, the pad PAD of FIG. 20 may be a component on which the pad of the micro LED is formed, such as a part where a chip circuit (e.g., a pixel driving circuit) is electrically connected to another external medium.

The mask of one example embodiment in accordance with the present disclosure may include a second slit that is a reduction of the first slit at a predetermined ratio, within a first slit, or a second slit that is a different size than the first slit. For example, but not limited to, the first slit may be a full-tone (FT) and the second slit may be a half-tone (HT). For example, a full-tone (FT) slit and a half-tone (HT) slit may have different sizes. For example, the size of the full-tone (FT) slit may, but not limited to, increase from the inside of the mask to the outside. The size of the full-tone (FT) slit may increase by 0.2 μm from the inside of the mask to the outside, but is not limited to this. For example, the size of the half-tone (HT) slit may be smaller from the inside of the mask to the outside, but is not limited to this. The size of the half-tone (HT) slit may be smaller by about 0.3 μm from the inside of the mask to the outside, but is not limited to this. For example, the mask may be, but not limited to, a mask as shown in FIG. 19 having a repeating pattern of full-tone (FT) slits and half-tone (HT) slits. For example, the mask may have, but not limited to, a rectangular shape. Other forms of masks may also be used, for example, the pattern may be formed on the photoresist layer PR such that the patterned area PA has a positive taper profile.

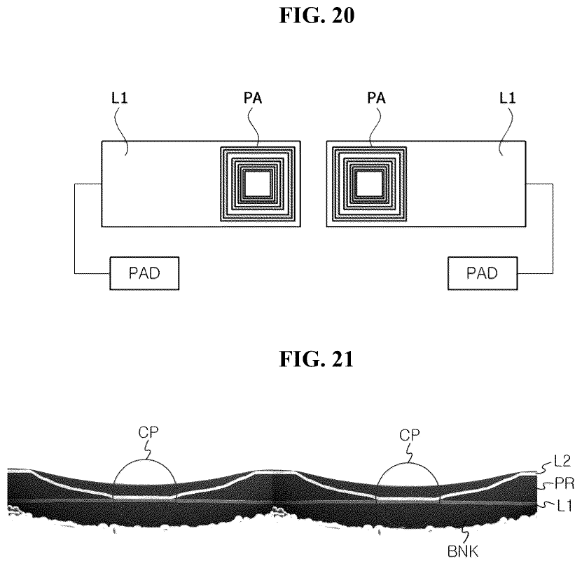

FIG. 21 is a diagram illustrating an implementation of a test element or a test element group according to an embodiment of the present disclosure.

With reference to FIG. 21, the first layer L1 may be positioned on the bank BNK, and the second layer L2 may be formed or deposited on the photoresist layer PR including the patterned area PA. Thus, the first layer L1 and the second layer L2 may be in contact with each other at the bottom portion CP of the patterned area PA. The first layer L1 may be connected to the pad PAD of FIG. 20.

In one example embodiment of the present disclosure, the first layer L1 may be a metal layer and the second layer L2 may be an indium layer. For example, the metal layer may be aluminum (Al), tungsten (W), titanium (Ti), copper (Cu), and the like, but embodiments of the present disclosure are not limited thereto. For example, the test element or the test element group may have a structure in which current is passed through a metal layer to an indium layer. For example, because the metal layer may be utilized as various signal wires and the indium layer may be utilized as various electrodes, it may be possible to determine the contact resistance for a certain structure in a display device using micro-LEDs (or micro light-emitting elements) by measuring the contact resistance between the metal layer and the indium layer. In one embodiment, the contact resistance of a micro-LED having a vertical structure may be determined. For example, the metal layer may be the first connection wire 121, but embodiments of the present disclosure are not limited thereto; for example, the indium layer may be a layer to which a light-emitting element (e.g., micro-LED) is bonded in a subsequent process, but embodiments of the present disclosure are not limited thereto.

The test element or the test element group according to one embodiment of the present disclosure may measure contact resistance between the first layer and the second layer by disposing the bank under the first layer, forming the patterned area with a positive taper profile using the mask, and contacting the first layer and the second layer through the patterned area over the bank. Therefore, the reliability of a display device using micro-LEDs may be judged.

The test element and a method of fabricating the same according to one or more embodiments of the present disclosure may be described as follows.

A test element according to one or more embodiments of the present disclosure may include: a base layer; a bank on a portion of the base layer; a first layer on the base layer and on the bank; a photoresist layer on the first layer, the photoresist layer including a patterned area; and a second layer positioned on the photoresist layer, wherein a height of a first area of the first layer on the bank is greater than a height of a second area of the first layer on the base layer.

According to one or more embodiments of the present disclosure, the patterned area may have a positive taper profile.

According to one or more embodiments of the present disclosure, the photoresiste layer is absent on the first are of the first layer in the patterned area.

According to one or more embodiments of the present disclosure, the first area of the first layer and the patterned area may be in contact over the bank.

According to one or more embodiments of the present disclosure, an inclined area of the first layer may be located on a side surface of the bank, and the first area of the first layer and the second area of the first layer may be connected to each other through the inclined area of the first layer.

According to one or more embodiments of the present disclosure, an entirety of the second layer may be connected through the patterned area.

According to one or more embodiments of the present disclosure, the patterned area may be formed using a mask that includes full-tone slits and half-tone slits.

According to one or more embodiments of the present disclosure, the sizes of the full-tone slit and the half-tone slit in the mask are different from each other, and the full-tone slit and the half-tone slit may be repeated.

According to one or more embodiments of the present disclosure, the contact resistance between the first and second layers may be measured through the portion in which the first area of the first layer and the patterned area are in contact.

According to one or more embodiments of the present disclosure, the contact resistance of the micro light-emitting element may be determined from the measured contact resistance.

According to one or more embodiments of the present disclosure, the micro light-emitting element may have a vertical structure.

According to one or more embodiments of the present disclosure, the first layer may include a metal, and the second layer may include indium.

A method of fabricating a test element according to one or more embodiments of the present disclosure may include: forming a bank on a base layer; forming a first layer including a first area on the bank and a second area on the base layer; forming a photoresist layer on the first layer; forming a patterned area in the photoresist layer by exposure; and forming a second layer on the photoresist layer and in the patterned area, wherein a height of a first area of the first layer on the bank is greater than a height of a second area of the first layer on the base layer.

According to one or more embodiments of the present disclosure, the patterned area may have a positive taper profile.

According to one or more embodiments of the present disclosure, the first area of the first layer and the second layer may directly contact in the patterned area.

According to one or more embodiments of the present disclosure, the photoresist layer is absent on the first are of the first layer in the patterned area.

According to one or more embodiments of the present disclosure, an inclined region of the first layer may be located on a side surface of the bank, and the first area of the first layer and the second region of the first layer may be connected to each other through the inclined region of the first layer.

According to one or more embodiments of the present disclosure, an entirety of the second layer may be connected through the patterned area.

According to one or more embodiments of the present disclosure, the forming of the patterned area may include irradiating light to the photoresist layer through a mask including full-tone slits and half-tone slits.

According to one or more embodiments of the present disclosure, the sizes of the full-tone slit and the half-tone slit in the mask are different from each other, and the full-tone slit and the half-tone slit may be repeated.

According to one or more embodiments of the present disclosure, the contact resistance between the first and second layers may be measured through the portion in which the first area of the first layer and the patterned area are in contact.

According to one or more embodiments of the present disclosure, the contact resistance of the micro light-emitting element the may be determined from the measured contact resistance.

According to one or more embodiments of the present disclosure, the micro light-emitting element may have a vertical structure.

According to one or more embodiments of the present disclosure, the first layer may include a metal, and the second layer may include indium.

It will be apparent to those skilled in the art that various modifications and variations can be made in the test element and the method of fabricating the same of the present disclosure without departing from the technical idea or scope of the disclosure. Thus, it is intended that the present disclosure cover the modifications and variations of this disclosure provided they come within the scope of the appended claims and their equivalents.

### LIST OF REFERENCE NUMBERS

100: Display panel
110: Substrate
120: Cover member
140: Support substrate
CB: Flexible circuit board
160: Printed circuit boards
1000: Display device

What is claimed is:

1. A test element, comprising:
a base layer;
a bank on a portion of the base layer;
a first layer on the base layer and on the bank;
a photoresist layer on the first layer, the photoresist layer including a patterned area; and
a second layer positioned on the photoresist layer,
wherein a height of a first area of the first layer on the bank is greater than a height of a second area of the first layer on the base layer.

2. The test element of claim 1, wherein the patterned area has a positive taper profile.

3. The test element of claim 1, wherein the first area of the first layer and the second layer are in direct contact in the patterned area.

4. The test element of claim 1, wherein the photoresist layer is absent on the first area of the first layer in the patterned area.

5. The test element of claim 1, wherein the first area of the first layer and the second area of the first layer are connected through an inclined area of the first layer on a side surface of the bank.

6. The test element of claim 1, wherein an entirety of the second layer is connected through the patterned area.

7. The test element of claim 1, wherein the patterned area is formed using a mask including full-tone slits and half-tone slits, wherein the sizes of the full-tone slits and the half-tone slits in the mask are different from each other, and the full-tone slits and the half-tone slits are repeated.

8. The test element of claim 3, wherein the contact resistance between the first and second layers is measured through the portion in which the first area of the first layer and the patterned area are in contact,
wherein the contact resistance of the micro light-emitting element is determined from the measured contact resistance,
wherein the micro light-emitting element has a vertical structure.

9. The test element of claim 1, wherein the first layer includes a metal, and the second layer includes indium.

10. A method of fabricating a test element, comprising:
forming a bank on a base layer;
forming a first layer including a first area on the bank and a second area on the base layer;
forming a photoresist layer on the first layer;
forming a patterned area in the photoresist layer by exposure; and
forming a second layer on the photoresist layer and in the patterned area,
wherein a height of a first area of the first layer on the bank is greater than a height of a second area of the first layer on the base layer.

11. The method of claim 10, wherein the patterned area has a positive taper profile.

12. The method of claim 10, wherein the first area of the first layer and the second layer are in direct contact in the patterned area.

13. The method of claim 10, wherein the photoresist layer is absent on the first area of the first layer in the patterned area.

14. The method of claim 10, wherein the first area of the first layer and the second area of the first layer are connected through an inclined area of the first layer on a side surface of the bank.

15. The method of claim 10, wherein an entirety of the second layer is connected through the patterned area.

16. The method of claim 10, the forming of the patterned area includes irradiating light to the photoresist layer through a mask including full-tone slits and half-tone slits.

17. The method of claim 16, wherein the sizes of the full-tone slits and the half-tone slits in the mask are different from each other, and the full-tone slits and the half-tone slits are repeated.

18. The method of claim 12, wherein the contact resistance between the first and second layers is measured through the portion in which the first area of the first layer and the patterned area are in contact.

19. The method of claim 18, wherein the contact resistance of the micro light-emitting element is judged from the measured contact resistance, wherein the micro light-emitting element has a vertical structure.

20. The method of claim 10, wherein the first layer includes a metal, and the second layer includes indium.
